(19) United States
(12) Patent Application Publication
(10) Pub. No.: US 2026/0150749 A1
(43) Pub. Date: May 28, 2026

(54) INTEGRATION OF LITHIUM NIOBATE PHOTONICS DEVICES

(71) Applicant: HyperLight Corporation, Cambridge, MA (US)

(72) Inventors: Mian Zhang, Cambridge, MA (US); Christian Reimer, Wellesley, MA (US); Dominick Scordo, Leonardo, NJ (US); Fan Ye, Lincoln, MA (US); Derek Matthew Kita, Somerville, MA (US); Jeffrey Cole Holzgrafe, Lexington, MA (US)

(21) Appl. No.: 19/397,685

(22) Filed: Nov. 21, 2025

Related U.S. Application Data
(60) Provisional application No. 63/724,843, filed on Nov. 25, 2024.

(51) Int. Cl. H01L 23/18; G02B 6/12; G02B 6/13; H10D 80/30

(52) U.S. Cl. CPC H10W 76/42; G02B 6/13; H10D 80/30; G02B 2006/1204; G02B 2006/12097

(57) ABSTRACT

A photonics device package is described. The photonics device package includes a thin film lithium-containing (TFLC) photonics integrated circuit (PIC) and an additional integrated circuit (IC). The TFLC PIC includes TFLC optical structures and electrodes. The TFLC structures include at least one TFLC electro-optic material. At least one of the TFLC structures includes a ridge and a slab and has a width not exceeding one micrometer. The TFLC PIC has a footprint. The TFLC structures occupy not more than fifty percent of the footprint. In addition, the TFLC structures are encapsulated in the TFLC PIC. The additional IC is mechanically coupled with the TFLC PIC after formation of the TFLC structures.

### CROSS REFERENCE TO OTHER APPLICATIONS

This application claims priority to U.S. Provisional Ser. No. 63/724,843 entitled INTEGRATION OF LITHIUM NIOBATE PHOTONICS DEVICES filed Nov. 25, 2024 which is incorporated herein by reference for all purposes.

### BACKGROUND OF THE INVENTION

Lithium-containing (LC) electro-optic materials, such as lithium niobate (LN) and/or lithium tantalate (LT), may be desired to be used in photonics integrated circuits (PICs). Thin film lithium-containing (TFLC) materials may include materials such as thin film LN (TFLN) and/or thin film LT (TFLT). TFLC PICs may support high data rates and low losses, which is desirable in applications such as data communication and/or telecommunication. Such TFLC photonic integrated circuits (TFLC PICs) are also desired to be integrated with other components. For example, a TFLC PIC may be desired to be used in conjunction with a silicon-based driver circuit and/or a silicon-based receiver. Thus, a TFLC PIC may be desired to be integrated with both electronic integrated circuits (ICs) and other, photonic ICs (e.g., silicon photonics ICs or other TFLC PICs).

However, challenges remain in combining TFLC devices with other ICs. For higher data rates, for example on the order of up to 400 Gbps, shorter electrical channels are desired. Thus, the TFLC PIC may be desired to be very close to the silicon-based devices. Thus, packaging TFLC PICs with silicon photonics ICs may be desired for such higher data rate devices. However, the TFLC device may be subject to optical and/or microwave/RF losses (losses in the electrical signal used to modulate the optical signal in the waveguides) that are greater than desired when integrated with silicon-based ICs. In addition, fabrication of TFLC PICs may be incompatible with fabrication of other ICs. For example, lithium is considered a contaminant for most semiconductor fabrication systems. As a result, conventional techniques for incorporating TFLC devices may utilize un-etched lithium-containing layers, such as un-etched TFLN. However, the performance of such devices may be unsuitable for higher data rate and/or higher performance devices. Accordingly, what is needed is an improved method for integrating TFLC PICs.

### BRIEF DESCRIPTION OF THE DRAWINGS

Various embodiments of the invention are disclosed in the following detailed description and the accompanying drawings.

FIGS. 1A-1E depict an embodiment of a thin film lithium-containing photonics integrated circuit and embodiments of integrated photonics packages incorporating embodiments of the thin film-lithium containing photonics integrated circuit.

FIGS. 2A-2B depict an embodiment of a portion of a thin film lithium-containing optical device usable in an integrated photonics package.

FIGS. 3A-3E depict an embodiment of a thin film lithium-containing photonics integrated circuit and embodiments of integrated photonics packages incorporating embodiments of the thin film-lithium containing photonics integrated circuit.

FIG. 4 depicts an embodiment of an integrated photonics package incorporating an embodiment of a thin film-lithium containing photonics integrated circuit.

FIG. 5 depicts an embodiment of an integrated photonics package incorporating an embodiment of a thin film-lithium containing photonics integrated circuit.

FIGS. 6A-6B depict embodiments of integrated photonics packages incorporating an embodiment of a thin film-lithium containing photonics integrated circuit.

FIG. 7 depicts an embodiment of an integrated photonics package incorporating an embodiment of a thin film-lithium containing photonics integrated circuit.

FIG. 8 depicts an embodiment of an integrated photonics package incorporating an embodiment of a thin film-lithium containing photonics integrated circuit.

FIG. 9 depicts an embodiment of an integrated photonics package incorporating an embodiment of a thin film-lithium containing photonics integrated circuit.

FIG. 10 depicts an embodiment of an integrated photonics package incorporating an embodiment of a thin film-lithium containing photonics integrated circuit.

FIG. 11 depicts an embodiment of an integrated photonics package incorporating an embodiment of a thin film-lithium containing photonics integrated circuit.

FIG. 12 depicts an embodiment of an integrated photonics package incorporating an embodiment of a thin film-lithium containing photonics integrated circuit.

FIG. 13 depicts an embodiment of an integrated photonics package incorporating an embodiment of a thin film-lithium containing photonics integrated circuit.

FIG. 14 depicts an embodiment of an integrated photonics package incorporating an embodiment of a thin film-lithium containing photonics integrated circuit.

FIG. 15 depicts an embodiment of an integrated photonics package incorporating an embodiment of a thin film-lithium containing photonics integrated circuit.

FIG. 16 depicts an embodiment of a thin film-lithium containing photonics integrated circuit usable in an embodiment of an integrated photonics package.

FIG. 17 depicts an embodiment of a thin film-lithium containing photonics integrated circuit usable in an embodiment of an integrated photonics package.

FIG. 18 depicts an embodiment of an integrated photonics package incorporating an embodiment of a thin film-lithium containing photonics integrated circuit.

FIG. 19 is a flow-chart depicting an embodiment of a method for providing a photonics package including a thin film lithium-containing photonics integrated circuit.

### DETAILED DESCRIPTION

The invention can be implemented in numerous ways, including as a process; an apparatus; a system; a composition of matter; a computer program product embodied on a computer readable storage medium; and/or a processor, such as a processor configured to execute instructions stored on and/or provided by a memory coupled to the processor. In this specification, these implementations, or any other form that the invention may take, may be referred to as techniques. In general, the order of the steps of disclosed processes may be altered within the scope of the invention. Unless stated otherwise, a component such as a processor or a memory described as being configured to perform a task may be implemented as a general component that is temporarily configured to perform the task at a given time or a specific component that is manufactured to perform the task. As used herein, the term ‘processor’ refers to one or more devices, circuits, and/or processing cores configured to process data, such as computer program instructions.

A detailed description of one or more embodiments of the invention is provided below along with accompanying figures that illustrate the principles of the invention. The invention is described in connection with such embodiments, but the invention is not limited to any embodiment. The scope of the invention is limited only by the claims and the invention encompasses numerous alternatives, modifications and equivalents. Numerous specific details are set forth in the following description in order to provide a thorough understanding of the invention. These details are provided for the purpose of example and the invention may be practiced according to the claims without some or all of these specific details. For the purpose of clarity, technical material that is known in the technical fields related to the invention has not been described in detail so that the invention is not unnecessarily obscured.

Lithium-containing (LC) electro-optic materials such as lithium niobate (LN) and lithium tantalate (LT) are valuable for photonic integrated circuits (PICs). Thin film lithium-containing (TFLC) materials, such as thin film LN (TFLN) and LT (TFLT), support high data rates and low losses, making them desirable for applications such as data communication and telecommunication. Integrating TFLC PICs with silicon-based driver or receiver circuits and other photonics integrated circuits is desirable for many applications, but challenges remain. For high data rates (e.g., up to 400 Gbps or more), shorter electrical channels are required. As a result, TFLC PICs may be close to silicon devices. However, TFLC PICs may experience greater optical and microwave, or RF, losses when integrated with silicon ICs. For example, the underfill used in bonding ICs may result in higher microwave losses for the TFLC PIC. Further, fabrication of TFLC optical structures may be incompatible with fabrication other ICs due to the potential for lithium contamination. Conventional methods using un-etched lithium layers may not deliver the performance desired for advanced devices. Therefore, improved integration methods for using TFLC PICs are desired.

A photonics device package is described. The photonics device package includes a thin film lithium-containing (TFLC) photonics integrated circuit (PIC) and an additional integrated circuit (IC). The TFLC PIC includes TFLC optical structures and electrodes. The TFLC structures include at least one TFLC electro-optic material, such as TFLN and/or TFLT. At least one of the TFLC structures includes a ridge and a slab (e.g., may be considered a ridge waveguide) and has a width not exceeding one micrometer. The TFLC PIC has a footprint. The TFLC structures occupy not more than fifty percent of the footprint. In some embodiments, the TFLC structures occupy not more than ten percent of the footprint and at least one percent of the footprint. In addition, the TFLC structures may be encapsulated in the TFLC PIC. For example, the TFLC structures may be covered in cladding and/or another material (e.g. dielectric(s)) and may reside on an oxide or other dielectric. Thus, at least the top, bottom, and sides of the TFLC structures are covered. However, the surfaces of the TFLC structures at the edge of the TFLC PIC may be covered or open to the environment. This flexibility may allow for managing optical coupling to the TFLC PIC. The additional IC is mechanically coupled with the TFLC PIC after formation and encapsulation of the TFLC structures. In some embodiments, at least a portion of the electrodes is formed after the TFLC PIC, and the additional IC are mechanically coupled.

The additional IC may be electrically coupled with the TFLC PIC through at least one via. The via(s) may extend through at least a portion of the TFLC PIC in a region of the footprint not occupied by the TFLC structures. The vias may also extend to or through the additional IC. The via(s) are at least partially filled by a conductive material.

In some embodiments, the TFLC PIC is flip-chip mounted on the additional IC, or vice versa. In some embodiments, the TFLC PIC is mounted top side up on the additional IC, or vice versa. The additional IC may be selected from an electronic IC and a photonics IC. The additional IC may be the electronic IC electrically coupled with the TFLC PIC. In some such embodiments, the photonics device package further includes the photonics IC that is optically and mechanically coupled with the TFLC PIC and the electronic IC. Thus, the photonics device package may include multiple ICs in addition to the TFLC PIC.

The photonics device package may have an average microwave dielectric index of less than 10 for a 100 GHz microwave signal for a region at a distance of not more than twenty micrometers centered at the ridge of the TFLC structure(s). The average microwave dielectric index is determined for the region but excludes metal areas of the region. In some embodiments, the region includes a portion of the TFLC PIC and a portion of the additional IC. Thus, microwave losses may be mitigated in the photonics device package.

The TFLC PIC may further include at least one waveguiding structure optically coupled with the at least one TFLC structure. In some such embodiments, the at least one waveguiding structure(s) surround at least a portion of the TFLC structure(s). The waveguiding structure(s) may exclude lithium as-fabricated. For example, such a waveguiding structure may include SiN. The TFLC structure(s) may include an intermediate portion between the ridge and the slab. The ridge has a first height. The intermediate portion has a second height less than the first height. The slab has a third height less than the second height. The additional IC may be a photonics IC having a waveguide optically coupled with the TFLC structure(s). In such embodiments, a portion of the waveguide is adjacent to at least a portion of the slab of the at least one TFLC structure. The photonics IC may have a cavity therein. At least a portion of the TFLC PIC may be in the cavity.

In some embodiments, a portion of the TFLC structure(s) is between a first electrode and a second electrode. The first electrode is closer to the additional IC than the portion of the at least one TFLC structure is. The second electrode is further from the additional IC than the portion of the at least one TFLC structure is. In some embodiments, the TFLC structure(s) are between a first electrode and a second electrode. The first and second electrodes may form a differential electrode pair.

A photonics device package is described. The photonics device package includes a TFLC PIC and an additional PIC optically and mechanically coupled with the TFLC PIC after formation of the TFLC structures. The TFLC PIC includes TFLC optical structures, a plurality of electrodes, and an additional waveguiding structure. The TFLC structures include at least one TFLC electro-optic material. At least one TFLC structure includes a ridge and a slab and having a width not exceeding one micrometer. The TFLC PIC has a footprint. The TFLC structures occupy not more than fifty percent of the footprint. The additional waveguiding structure consists of material(s) selected from at least one optical material excluding lithium. The TFLC structures are encapsulated in the TFLC PIC. The additional PIC includes a waveguide. The additional waveguiding structure is configured to optically couple the at least one TFLC structure with the waveguide.

A method for forming a photonics device package is described. The method includes providing a TFLC PIC and mechanically coupling an additional IC with the TFLC PIC after formation of TFLC structures in the PIC. The TFLC PIC includes the TFLC optical structures and electrodes. The TFLC structures include at least one TFLC electro-optic material. At least one TFLC structure of the plurality of TFLC structures includes a ridge and a slab and has a width not exceeding one micrometer. The TFLC PIC has a footprint. The TFLC structures occupy not more than fifty percent of the footprint. The TFLC structures are encapsulated in the TFLC PIC. In some embodiments, the method also includes forming, after the mechanically coupling, at least one via extending through at least a portion of the TFLC PIC and at least a portion of the additional IC in a region of the footprint not occupied by the plurality of TFLC structures. The method may also include at least partially filling the via(s) with a conductive material such that the additional IC is electrically coupled with the TFLC PIC through at least one via.

Various features of the electro-optic devices are described herein. One or more of these features may be combined in manners not explicitly described herein. For example, TFLC waveguides having three etches and additional waveguiding layers, other TFLC waveguides and PDs, electrodes having extensions in the TFLC PIC and photodiodes and/or drivers in the additional IC, and/or other combinations may be present.

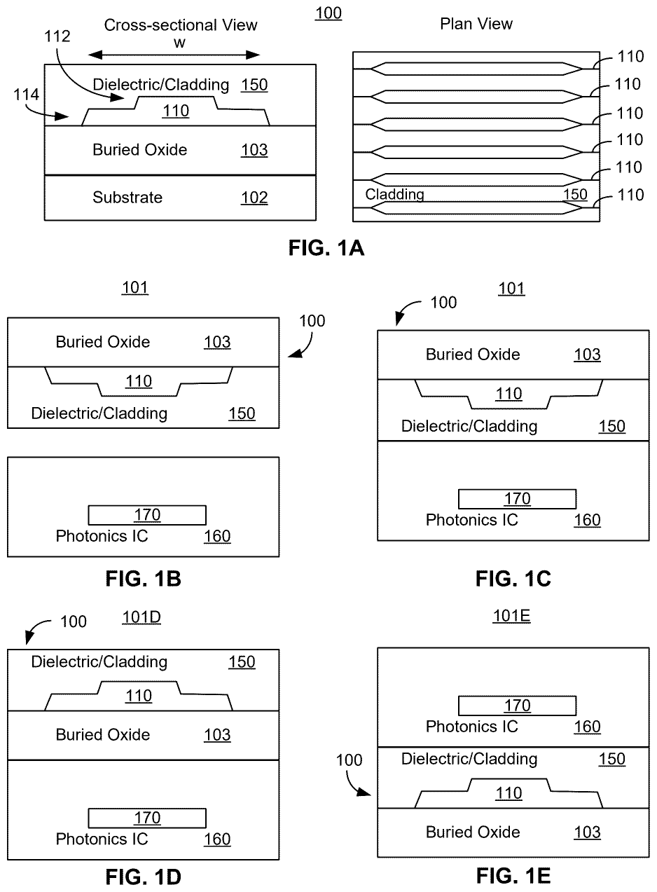

FIGS. 1A-1E depict an embodiment of thin film lithium-containing (TFLC) photonics integrated circuit (PIC) 100 and embodiments of integrated photonics packages 101, 101D, and 101E incorporating TFLC PIC 100. More specifically, FIG. 1A depicts TFLC PIC 100. FIGS. 1B-1C, 1D, and 1E depict integrated photonics device packages 101, 101D, and 101E, respectively. Other components are generally present but are not shown for clarity. For example, photonics package 101 may include electrical input and output (I/O) and/or optical I/O (e.g., a fiber array unit). Although one TFLC PIC 100 and one additional IC 160 are shown, multiple TFLC PICs and/or multiple additional ICs may be present in particular integrated photonics device packages.

FIG. 1A depicts cross-sectional and plan views of TFLC PIC 100 prior to integration. TFLC PIC 100 includes TFLC optical component(s) 110 and electrodes (not shown in FIGS. 1A-1E for clarity). TFLC PIC 100 may also reside on substrate 102 and have a buried oxide (BOX) layer 103. For example, BOX layer 103 may include or consist of a layer of silicon dioxide that is at least three micrometers thick. TFLC structures 110 include at least one TFLC electro-optic material, such as TFLN and/or TFLT. For example, TFLC PIC 100 may include waveguides, splitters, bends, mode converters, polarization beam rotators, and/or other optical components used to transmit and/or modify the optical signal carried by TFLC PIC 100. Electrodes may be used in conjunction with waveguide(s), for example for optical modulation (e.g. via the electro-optic effect). In the embodiment depicted in FIG. 1A, TFLC optical components 110 include waveguides in Mach-Zehnder interferometers. Consequently, TFLC optical components 110 are also referred to as TFLC waveguides 110. Other configurations and/or other optical structures formed in TFLC waveguides 110 are possible. In a modulation region (a region proximate to electrodes), each TFLC waveguide 110 has been split into two arms. Although depicted as extending in a straight line from one edge to the opposing edge of TFLC PIC 100, waveguides 110 may have another configuration.

In the region shown in the cross-sectional view, TFLC waveguide 110 includes a ridge portion 112 and a slab portion 114 (labeled only in FIG. 1A). Further, the slab portion terminates (has side edges). Thus, the TFLC layer from which TFLC waveguide 110 is formed has undergone at least two etches in some embodiments. TFLC waveguide 110 may be considered to have a double staircase structure. In some embodiments, the first etch removes at least twenty percent depth of whole TFLC layer film thickness. In some embodiments, one etch (e.g. the first etch) removes at least thirty percent of the TFLC layer thickness. The etch may remove at least forty percent of the TFLC layer thickness, at least fifty percent of the thickness of the TFLC layer, or at least seventy percent of the layer thickness. In some embodiments, the other etch (e.g., the second etch) removes the remaining thickness of the TFLC layer.

The etches also form the sidewall angles for TFLC waveguide 110. The sidewall angles for ridge 112 and/or slab 114 may not exceed ninety degrees and are typically less than ninety degrees (e.g., not quite vertical). For example, the sidewall angles may be less than 85 degrees, less than 80 degrees, less than 75 degrees, and/or less than 70 degrees The sidewall angles may be desired to be steep. For example, the sidewall angles may be at least forty-five degrees, at least fifty-five degrees, or at least sixty degrees. The sidewalls may also have a lower surface roughness (e.g., less than ten nanometers), allowing for low optical losses in waveguides 110 of TFLC PIC 100. TFLC waveguide 110 has a width (e.g., a smallest feature size), w. In some embodiments, the width of TFLC waveguide (i.e., TFLC optical structure) 110 is not more than one micrometer. This may be the smallest feature size for the TFLC waveguide 110. In some embodiments, the smallest feature size in the TFLC waveguide 110 is not more five hundred nanometers. In some such embodiments, the smallest feature size (e.g., the smallest width) of TFLC waveguide 110 is not more than two hundred nanometers.

In some embodiments, the TFLC layer from which TFLC waveguide 110 is formed has a thickness of less than two micrometers or less than one micrometer. Thus, TFLC waveguide 110 may have a thickness of less than two micrometers, less than one micrometers, less than six hundred nanometers, less than five hundred nanometers, or less than four hundred nanometers. The thickness of TFLC waveguide 110 may be at least fifty nanometers. In some embodiments, the TFLC layer has a thickness of at least two hundred and fifty nanometers. For example, TFLC waveguide 110 may be nominally three hundred nanometers or three hundred and fifty nanometers thick with, for example, a 10-15 nanometer variation. The thickness of TFLC waveguide 110 (e.g. to the top of ridge 112) may be not more than three hundred nanometers, not more than three hundred and fifty nanometers, not more than four hundred nanometers, not more than five hundred nanometers, not more than six hundred nanometers, not more than seven hundred nanometers, not more than one micrometer, not more than 1.5 micrometer, and/or not more than two micrometers. In some embodiments, the thickness of TFLC waveguide 110 may at least more than three hundred nanometers, at least three hundred and fifty nanometers, at least four hundred nanometers, at least five hundred nanometers, at least six hundred nanometers, at least seven hundred nanometers, at least one micrometer, or at least 1.5 micrometer,

The plan view of TFLC PIC 100 indicates the sparsity of TFLC optical structures 110. In some embodiments, the only portion of the TFLC layer remaining in completed TFLC PIC 100 is in TFLC optical structures 150. In some embodiments, the TFLC material (e.g., waveguides 110) occupies not more than fifty percent of the footprint (i.e. the area of TFLC PIC 100 shown in FIG. 1A) and greater than zero percent of the area of the footprint (i.e. TFLC waveguide(s) 110 are present). In some embodiments, TFLC material (e.g., waveguides 110) occupy not more than forty percent of the area of the footprint, not more than thirty percent of the area of the footprint, not more than twenty percent of the area of the footprint, or not more than ten percent of the area of the footprint of TFLC PIC 100. The TFLC electro-optic material (e.g., TFLC waveguide 110) may also occupy at least one percent, at least two percent, or at least five percent of the area of TFLC PIC 100. Thus, there are relatively large regions of TFLC PIC 100 that are distal from the remaining TFLC electro-optic material(s).

Further, TFLC waveguides 110 have been encapsulated. TFLC PIC 100 includes BOX layer 103 and cladding 150. As can be seen in the cross-sectional view of FIG. 1A, the sides and top of waveguide(s) 110 are covered in cladding 150. In some embodiments, cladding 150 is a dielectric such as silicon dioxide. The bottoms of TFLC waveguides 110 are adjacent to BOX 110. Thus, the top, bottom and sides of TFLC waveguide 110 are covered in other material(s) that may include or be stable dielectrics. As such, TFLC waveguides 110 may be considered to be encapsulated. Even if other layer(s) are interposed between TFLC waveguides 110 and BOC layer 103 and/or cladding 150, such layer(s) may be considered to encapsulate TFLC waveguides 110. For example, a lithium diffusion barrier layer may surround some or all of TFLC waveguides 110. However, in some embodiments, the ends of TFLC waveguides 110 may or may not be covered by another material. For example, the portions of TFLC waveguides 110 at or near the side edges of TFLC PIC 100 may be exposed. In some embodiments, the portions of TFLC waveguides 110 at or near side edges of TFLC PIC 100 may not be exposed. Exposing TFLC waveguides 110 a or near the edges of TFLC PIC 100 may facilitate coupling of optical signals into and/or out of TFLC PIC 100. Such TFLC waveguides 110 are still considered to be encapsulated. Encapsulation of TFLC waveguides 100 may improve fabrication of TFLC PIC 100 because contamination of fabrication systems due to processing after encapsulation may be reduced.

FIGS. 1B-1E depict photonics device package 101, 101D, and 101E. All photonics device packages 101, 101D, and 101E use TFLC PIC 100. However, substrate 102 has been removed. FIG. 1B depicts photonic device package 101 during integration. Thus, TFLC PIC 100 has not been mechanically, electrically, or optically coupled with additional IC 160. In the embodiment shown, IC 160 is a silicon photonics IC. Thus, IC 160 includes a silicon photonics waveguide 170. In some embodiments, other photonics ICs with other and/or additional components (including but not limited to other waveguides) may be present. For example, photonics IC 170 may include laser(s), monitor photodiode(s) (PD(s)), and/or other optical components. In some embodiments, IC 160 may be an electronic IC (EIC). For example, such an EIC may include driver(s) and/or sensors. Thus, the IC(s) with which TFLC PIC 100 is coupled may be an EIC or a PIC. Further multiple ICs may be integrated with TFLC PIC 100. Thus, IC 160 may be a silicon-based IC(s) and/or other IC(s). For example, IC 160 may include a silicon-based transmitter IC (e.g., an electrical IC that includes driver and/or other circuitry) and/or a silicon-based receiver circuit. IC(s) 160 may also include silicon (or other) support structures which provide mechanical support and/or electrical connection to TFLC PIC 100 and/or other ICs. ICs 160 may be electrically and/or optically connected with TFLC PIC 100. For simplicity, one PIC 160 is shown as being coupled with TFLC PIC 100. Other and/or additional ICs may be coupled with TFLC PIC 100 in other embodiments.

FIG. 1C depicts integrated photonics package 101 after TFLC PIC 100 has been aligned with and mechanically coupled to IC 160. In integrated photonics package 101, TFLC PIC 100 has been flip-chip bonded with PIC 160. FIG. 1D depicts integrated photonics package 101D after TFLC PIC 100 has been aligned with and mechanically coupled to IC 160. In integrated photonics package 101, TFLC PIC 100 has been bonded with PIC 160. Thus, BOX layer 103 is between TFLC waveguide 110 and IC 160. FIG. 1E depicts integrated photonics package 101E after photonics IC 160 has been aligned with and mechanically coupled to TFLC PIC 100. In the embodiment shown in FIG. 1E, IC 160 has been bonded to TFLC PIC 100. In other embodiments, IC 160 may be flip-chip bonded with TFLC PIC 100.

In operation, TFLC PIC 100 transmits and modulates optical signals in waveguides 110. Other operations may also be performed on the optical signals carried by waveguides 110. Waveguide 110 may also be optically coupled with waveguide 170. Thus, optical signals may be transferred between TFLC PIC 100 and IC 160. Light from a single continuous wave source may be shared between the dielectrics of ICs 100 and 160. The coupling between the waveguides 110 and 170 may be evanescent coupling, coupling through gratings (not shown in FIGS. 1B-1E), coupling through edge coupling, or made in another matter. There may be additional waveguiding materials in dielectric material(s) of one or both of TFLC PIC 100 and IC 160.

Thus, the benefits of TFLC PIC 100 and the functions of IC 160 may be combined in a single device 101. Such a device may enjoy the benefits of the TFLC electro-optic materials as well as the features of IC 160. For example, TFLC PIC 100 may provide optical modulation with losses in the modulation region of less than five dB, less than three dB, less than one dB, or less than 0.5 dB, while allowing the optical signal to be transferred to IC 160 for routing, modulation, or other functions. In addition, waveguides 110 and 170 are in proximity. Thus, higher data rate optical signals may not only be transmitted through individual ICs 100 and 160, but also between ICs 100 and 160.

Completion of integrated optical device packages 101, 101D and/or 101E may be accomplished in various ways. Additional processing, such as etching and filling vias, formation of portions of electrodes, formations of electrodes and/or other structures may occur after the coupling of the TFLC PIC 100 and the other IC(s) 160 into integrated packages 101, 101D, and/or 101E. Formation of such other structures may also occur separately from fabrication of the TFLC PIC 100. For example, vias (not shown) may be formed and filled with metal to provide electrical connection to the TFLC PIC 100 and between TFLC PIC 100 and other devices after the TFLC PIC 100 and IC 160 are affixed together. Similarly, vias (not shown) may be formed and filled with metal to provide electrical connection to the IC 160 and between IC 160 and other devices (e.g., TFLC PIC 100) after the TFLC PIC 100 and IC 160 are affixed together.

Because the TFLC electro-optic material and TFLC structures 110 formed thereof are sparse, additional structures may be formed without making physical contact with the TFLC electro-optic material. For example, vias may be formed (e.g. to or through cladding 150 and/or BOX layer 103) without removing portion(s) of or otherwise impacting the TFLC electro-optic material. Thus, contamination to other non-lithium fabrication systems may be reduced or eliminated. Consequently, both performance and manufacturing of integrated photonic devices 101, 101d, and/or 101e may be improved.

TFLC PIC 100 includes TFLC optical component(s) 110 and electrodes, among other structures. For example, TFLC PIC 100 may include waveguides, splitters, bends, mode converters, polarization beam rotators, and/or other optical components used to transmit and/or modify the optical signal carried by TFLC PIC 100. Electrodes may be used in conjunction with waveguide(s), for example for optical modulation (e.g. via the electro-optic effect).

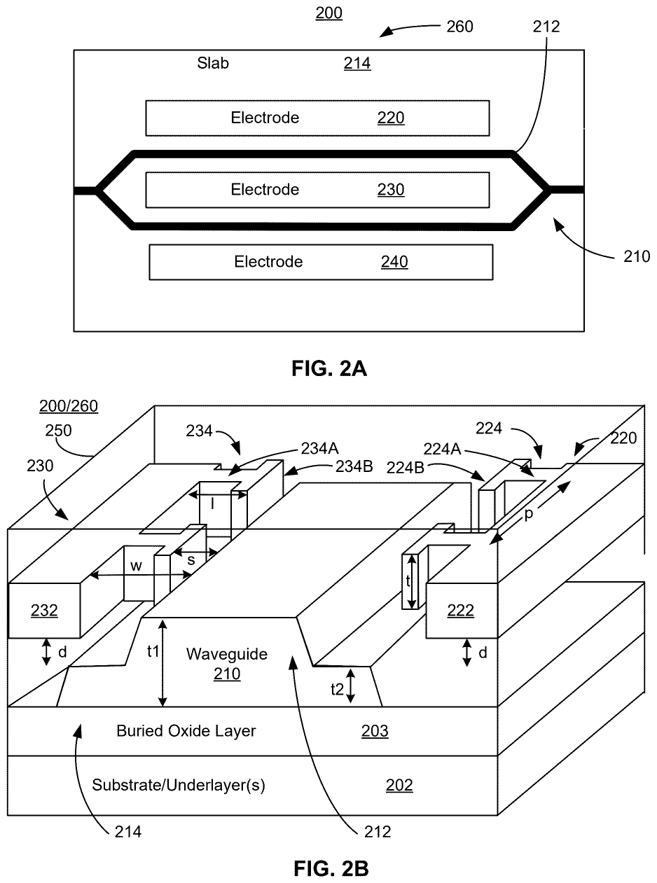

For example, FIGS. 2A-2B depict an embodiment of a portion of TFLC PIC 200 usable in an integrated photonics package, such as integrated photonics packages 101, 101D and/or 101E. For example, photonics device 200 may be used as part or all of a modulator used in TFLC PIC 100. FIG. 2B is a perspective view of a portion of photonics device 200. FIGS. 2A-2B are not to scale. Only a portion of photonics device 200 is shown. Photonics device 200 may include other and/or additional structures that are not shown for simplicity. Further, although particular configurations are shown, other configurations are possible.

Photonics device 200 is on a substrate structure that includes substrate 202 and buried oxide (BOX) layer 203. In some embodiments, substrate 202 is a silicon substrate. Substrate 202 may also include other layers. In some embodiments, substrate 202 may be glass, quartz, silicon-on-insulator, and/or other low microwave loss dielectrics. Substrate 202 may be one hundred micrometers or more thick. BOX layer 203 may be a silicon dioxide layer. In some embodiments, BOX layer 203 may be at least three micrometers thick and not more than fifteen micrometers thick. In some embodiments, the substrate structure may be configured differently. Also shown is cladding 250, which may be formed of silicon dioxide.

Photonics device 200 includes waveguide 210 and electrodes 220, 230, and 240. In some embodiments, photonics device 200 may be configured as or include a modulator (or portion thereof). Thus, photonics device 200 may be considered to include modulation region 260. Other regions, such as a bend region, may be present. Modulator 200 is shown as configured as a Mach-Zehnder modulator. Other configurations for phase and/or amplitude modulation are possible. For clarity, only the portion of electrodes 220, 230, and 240 proximate to waveguide 210 are shown. Stated differently, electrodes 220, 230, and 240 are shown in modulation region 260.

Waveguide 210 may be considered to include ridge 212 as well as slab 214. Ridge 212 has a height, t1, greater than the height, t2, of slab 214. Although shown as rectangles, ridge 212 and/or slab 214 have other shapes, such as trapezoids and/or other analogous shapes. In addition, slap 212 may terminate closer to ridge 214 than at least a portion of electrode(s) 220 and/or 230. Photonics device 200 includes electro-optic optic material(s), such as TFLC materials (e.g. TFLN and/or TFLT). More specifically, ridge 212 and slab 214 include electro-optic materials, such as TFLC materials. In some embodiments, the waveguide 210 consists of TFLC materials such as TFLN and/or TFLT. In the embodiment shown, ridge 212 and slab 214 are formed of the same material. In some embodiments, ridge 212 and slab 214 may include different materials. Waveguide 210, and more particularly ridge 212, may be used to propagate the optical signal. The optical mode may be well confined to ridge 212 and/or ridge 212 in combination with a portion of nearby slab 214. Slab 214 provides increased electro-optic modulation efficiency. In particular, slab 214 aids in directing the electric field generated by the signal(s) in electrodes 220, 230, and 240 to optical mode 213 in modulation region 260. Thus, a higher modulation for a given electric field may be obtained. As a result, V-pi (and V-pi-L) may be reduced.

Electrodes 220, 230, and 240 may carry electrode signals used to modulate the optical signals (e.g. light) carried by waveguide 210 via electro-optic modulation. Electrode(s) 220 and/or 230 are configured to carry a traveling wave (e.g. a microwave or RF electrode signal) that modulates the optical signal carried by waveguide 210 via the electro-optic effect. For example, the electrode signals may provide electro-optic modulation up to frequencies of 100 GHz, 200 GHz, 500 GHZ or higher. In some embodiments, modulator 210 may provide modulation from at or near DC to frequencies of 100 GHz, 200 GHz, 500 GHz, or more. The modulation may also have a wide window, for example an operation bandwidth of at least 20 GHz. Electrode signals carried by electrodes 220, 230, and 240 may be configured in a variety of manners. For example, electrode 230 may carry a microwave signal, while electrodes 220 and 240 are ground. Electrode 230 may carry a signal of a first polarity, while electrodes 220 and 240 carry signals of opposite polarity (i.e. in a differential configuration). Other configurations (including but not limited to another number of electrodes) are possible.

Electrodes 220, 230, and/or 240 may include extensions. Embodiments of analogous electrodes may be found in co-pending U.S. patent application Ser. No. 17/843,906, entitled ELECTRO-OPTIC DEVICES HAVING ENGINEERED ELECTRODES, which is a continuation of U.S. patent application Ser. No. 17/102,047 entitled ELECTRO-OPTIC DEVICES HAVING ENGINEERED ELECTRODES, filed Nov. 23, 2020, which claims priority to U.S. Provisional Ser. No. 62/941,139 entitled THIN-FILM ELECTRO-OPTIC MODULATORS filed Nov. 27, 2019, U.S. Provisional Ser. No. 63/033,666 entitled HIGH PERFORMANCE OPTICAL MODULATORS filed Jun. 2, 2020, and U.S. Provisional Ser. No. 63/112,867 entitled BREAKING VOLTAGE-BANDWIDTH LIMIT IN INTEGRATED LITHIUM NIOBATE MODULATORS USING MICRO-STRUCTURED ELECTRODES filed Nov. 12, 2020, all of which are incorporated herein by reference for all purposes. In other embodiments, extensions may be omitted from some or all of electrodes 220, 230, and/or 240. Electrodes 220, 230, and 240 may carry differential electrical signals, a single electrical signal (e.g. a signal and ground), or other signal(s).

Electrode 230 includes a channel region 232 and extensions 234 (of which only one is labeled in FIG. 2B). Similarly, electrode 220 includes channel region 222 and extensions 224 (of which only one is labeled in FIG. 2B). In some embodiments, extensions 224 or 234 may be omitted from electrode 220 or electrode 230, respectively. Extensions 224 and 234 may be closer to ridge 212 than channel region 222 and 232, respectively, are. For example, the distance s from extensions 224 and 234 to waveguide ridge 212 is less than the distance w from channels 222 and 232 to waveguide ridge 212. Extensions 224 may be closer to electrode 230 (e.g. extensions 234 and/or channel 232) than channel 222 is. Similarly, extensions 234 may be closer to electrode 220 e.g. extensions 224 and/or channel 222) than channel 232 is.

Extensions 224 and 234 are in proximity to ridge 212. For example, extensions 224 and 234 are a vertical distance, d from slab 214 of TFLC waveguide 210. The vertical distance to TFLC waveguide 210 may depend upon the cladding 250 used. The distance d is highly customizable in some cases. For example, d may range from zero (or less if electrodes 220 and 230 contact or are embedded in slab portion 214) to greater than the height of ridge 212. In embodiments in which slab 214 terminates closer to ridge 212 than channel regions 222 and 232, d may be zero (same level as the top surface of slab 214), positive (further from substrate 202 than the top surface of slab 214), or negative (further from substrate 202 than the top surface of slab 214). However, d is generally still desired to be sufficiently small that electrodes 220 and 230 can apply the desired electric field to ridge 212. Extensions 224 and 234 are also a distance, s, from ridge 212. In some embodiments, s<0 (i.e., extensions 224 and/or 234 may extend over the top of ridge 212 or below waveguide 210). Extensions 224 and 234 are desired to be sufficiently close to TFLC waveguide 210 (e.g. close to ridge 212) that the desired electric field and index of refraction change can be achieved. However, extensions 224 and 234 are desired to be sufficiently far from TFLC waveguide 210 (e.g. from ridge 212) that their presence does not result in undue optical losses. Although shown next to ridge 212, extensions 224 and/or 234 may extend above and/or below ridge 212.

In the embodiment shown, extensions 224 have a connecting portion 224A and a retrograde portion 224B. Retrograde portion 224B is so named because a part of retrograde portion may be antiparallel to the direction of signal transmission through electrode 220. Similarly, extensions 234 have a connecting portion 234A and a retrograde portion 234B. Thus, extensions 224 and 234 have a “T”-shape. In some embodiments, other shapes are possible. For example, extensions 224 and/or 234 may have an “L”-shape, may omit the retrograde portion, may be rectangular, trapezoidal, parallelogram-shaped, may partially or fully wrap around a portion of ridge 212, and/or have another shape. Similarly, channel regions 222 and/or 232, which are shown as having a rectangular cross-section, may have another shape. Further, extensions 224 and/or 234 may be different sizes. Although all extensions 224 and 234 are shown as the same distance from ridge 212, some of extensions 224 and/or some of extensions 234 may be different distances from ridge 212. Channel regions 222 and/or 232 may also have a varying size.

Also indicated in FIG. 2B is thickness, t, of extensions 224 and 234. In the embodiment shown, channels 222 and 232 have the same thickness. In some embodiments, the thickness of extensions 224 and/or 234 may vary. For example, extensions 224 may be thinner (or thicker) than extensions 234. Further, different extensions 224 may have different thicknesses. Similarly, different extensions 234 may have different thicknesses. Extensions 224 and/or 234 may also have a different thickness than channels 222 and/or 232. For example, extensions 224 and/or 234 may be thinner (or thicker) than channels 222 and/or 232. Different portions of extensions 224 and/or 234 may also have different thicknesses. For example, retrograde portions 224B and/or 234B may be thinner (or thicker) than connecting portions 224A and/or 234B. Thus, TFLC PICs 200 and 100 may have a variety of configurations, components, and functions. Performance of TFLC PICs 200 and 100 may be superior to that of other, non-TFLC PICs.

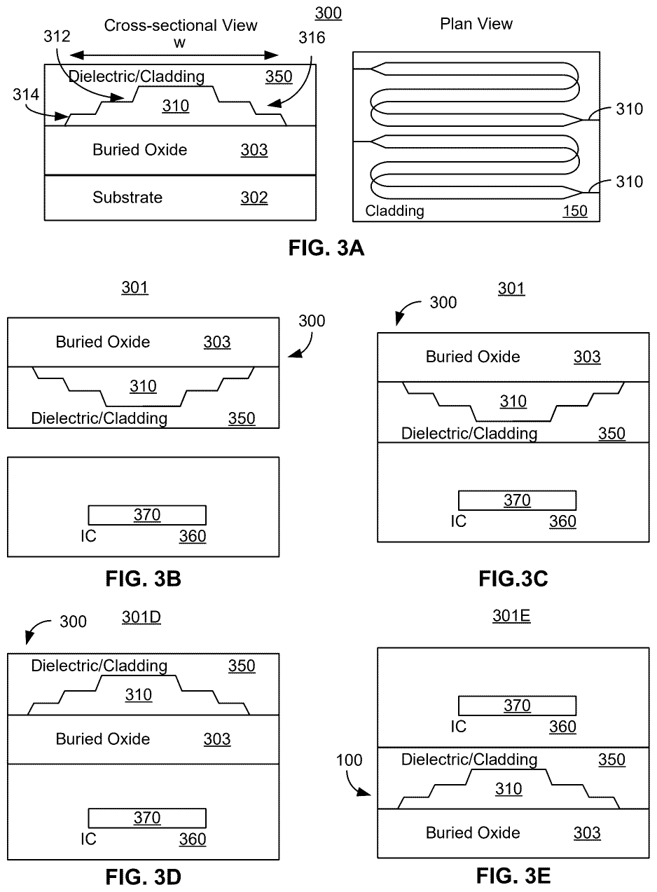

FIGS. 3A-3E depict an embodiment of thin film lithium-containing (TFLC) photonics integrated circuit (PIC) 300 and embodiments 301, 301D, and 301E of integrated photonics packages incorporating TFLC PIC 300. More specifically, FIG. 3A depicts TFLC PIC 300. FIGS. 3B-3C, 3D, and 3E depict integrated photonics device packages 301, 301D, and 301E, respectively. Other components are generally present but are not shown for clarity. For example, photonics package 301 may include electrical input and output (I/O) and/or optical I/O (e.g., a fiber array unit). Although one TFLC PIC 300 is shown, multiple TFLC PICs and/or multiple additional ICs may be present in particular integrated photonics device packages.

FIG. 3A depicts cross-sectional and plan views of TFLC PIC 300 prior to integration. TFLC PIC 300 is analogous to TFLC PIC 100. Analogous components are labeled similarly. TFLC PIC 300 includes TFLC optical component(s) 310, electrodes (not shown in FIGS. 3A-3E for clarity), and cladding 350 residing on substrate 302 that may be analogous to TFLC optical component(s) 110, electrodes, and cladding 150 residing on substrate 102. For example, TFLC PIC 300 may include waveguides, splitters, bends, mode converters, polarization beam rotators, and/or other optical components used to transmit and/or modify the optical signal carried by TFLC PIC 300. Electrodes may be used in conjunction with waveguide(s), for example for optical modulation (e.g. via the electro-optic effect). In the embodiment depicted in FIG. 3A, TFLC optical components 310 include waveguides in Mach-Zehnder interferometers. Consequently, TFLC optical components 310 are also referred to as TFLC waveguides 310. Other configurations and/or other structures formed in TFLC waveguides 310 are possible. In a modulation region (a region proximate to electrodes), each TFLC waveguide 310 has been split into two arms. In addition, waveguides 310 are also shown as having bends. In some embodiments, waveguides 310 may have bend radius(es) that may be less than five hundred micrometers, less than two hundred micrometers, less than one hundred micrometers, less than eight micrometers, or less than fifty micrometers.

In the region shown in the cross-sectional view, TFLC waveguide 310 includes a ridge portion 312, a slab portion 314, and an intermediate portion 316 between the ridge and slab portions (labeled only in FIG. 3A). Further, the slab portion 314 terminates (has side edges). Thus, the TFLC layer from which TFLC waveguide 310 is formed has undergone at least three etches in some embodiments. The etches may remove analogous portions of the layer forming TFLC waveguide 310 as for TFLC waveguide 110. The sidewall angles and waveguide 310 thicknesses may also be in analogous ranges as for waveguides 110 of TFLC PIC 100. In addition, the sparsity of the TFLC electro-optic material (e.g. TFLC waveguides 310) in TFLC PIC 300 may be in analogous ranges as for TFLC PIC 100. TFLC waveguides 310 have been encapsulated in a manner analogous to TFLC waveguide 110. Thus, in some embodiments, the ends of TFLC waveguides 310 at edges of TFLC PIC 300 may or may not be covered by another material.

FIGS. 3B-3E depict photonics device package 301, 301C, 301D, and 301E that are analogous to photonics device packages 101, 101C, and 101D, respectively. All photonics device packages 301, 301C, 301D, and 301 use TFLC PIC 300. In FIG. 3B, TFLC PIC 300 has not been mechanically, electrically, or optically coupled with additional IC 360. IC 360 is analogous to IC 160. Thus, waveguide 370 is analogous to waveguide 170. FIG. 3C depicts integrated photonics package 301 after TFLC PIC 300 has been aligned with and mechanically coupled to IC 360. In integrated photonics package 301, TFLC PIC 300 has been flip-chip bonded with PIC 360. FIG. 3D depicts integrated photonics package 301D after TFLC PIC 300 has been aligned with and mechanically coupled to IC 360. In integrated photonics package 301, TFLC PIC 300 has been bonded with PIC 360. Thus, BOX layer 303 is between TFLC waveguide 310 and IC 360. FIG. 3E depicts integrated photonics package 301E after photonics IC 360 has been aligned with and mechanically coupled to TFLC PIC 300. In the embodiment shown in FIG. 3E, IC 360 has been bonded to TFLC PIC 300. In other embodiments, IC 360 may be flip-chip bonded with TFLC PIC 300.

Integrated device packages 301, 301D and 301E function in an analogous manner to integrated device packages 101, 101D, and 101E, respectively. Although waveguide 110 and waveguide 310 differ in the number of edges, one of ordinary skill in the art will recognize that waveguides 110 and 310 may have varying heights and numbers of “steps” in different locations. For example, in some embodiments, the waveguide may have the form of waveguide 310 in some regions, the form of waveguide 110 in other regions, and/or another shape (e.g. a channel waveguide having a single step, or an asymmetrically shaped waveguide) in other regions. Thus, the height and the shape of the waveguide may be tailored for various functions. Further, waveguide 370 may be optically coupled with waveguide 310 in a manner analogous to those described for waveguides 110 and 170.

Integrated devices packages 301, 301D, and 301E may share the benefits of integrated device packages 101, 101D, and 101E. For example, the functions of TFLC PIC 300 and IC 360 may be combined in a single device 301, 301B, or 301C. Such a device may enjoy the benefits of the TFLC electro-optic materials of TFLC PIC 300 as well as the features of IC 360. For example, TFLC PIC 300 may provide optical modulation with losses in the modulation region, data rates, and ability to couple between ICs 300 and 360 as for TFLC PIC 100. In addition, formation of integrated devices packages 301, 301D, and 310E may be completed in an analogous manner to integrated device packages 101, 101D, and 101E. Thus, manufacturing may also be facilitated. Consequently, both performance and manufacturing of integrated photonic devices 301, 301D, and/or 301E may be improved.

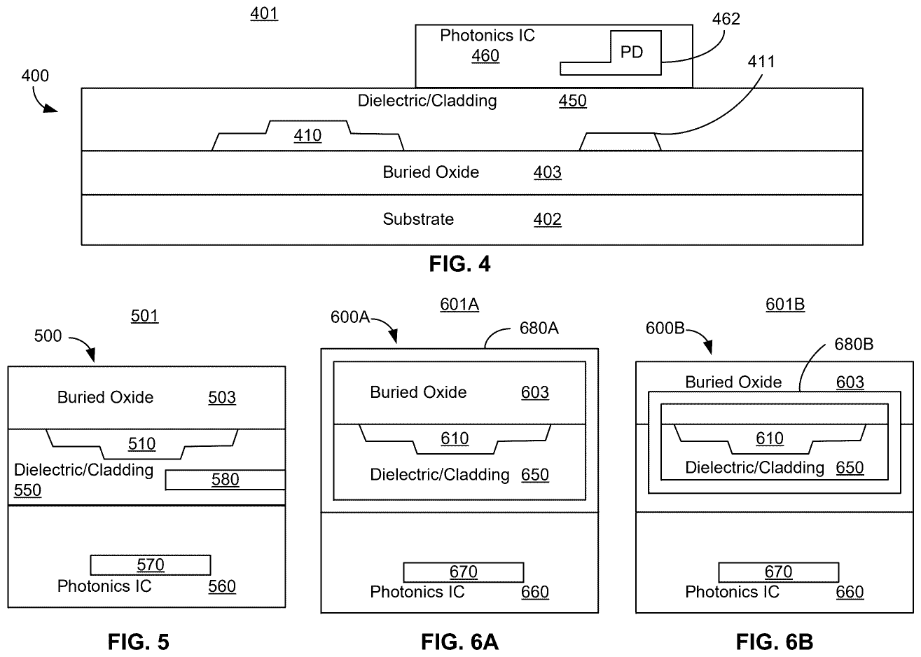

FIG. 4 depicts an embodiment of integrated photonics package 401 incorporating an embodiment of TFLC PIC 400 and photonics IC 460. Other components are generally present but are not shown for clarity. For example, photonics package 401 may include electrical input and output (I/O) and/or optical I/O (e.g., a fiber array unit). Although one TFLC PIC 400 is shown, multiple TFLC PICs and/or multiple additional ICs may be present in particular integrated photonics device packages.

TFLC PIC 400 is analogous to TFLC PIC 100. Analogous components are labeled similarly. TFLC PIC 400 includes TFLC optical component(s) (e.g., TFLC waveguides) 410, electrodes (not shown for clarity), and cladding 450 residing on substrate 402 that may be analogous to TFLC optical component(s) 110/310, electrodes, and cladding 150/350 residing on substrate 102/302. In the embodiment shown, TFLC waveguide 410 includes a slab portion and a rib portion. Other configurations are possible. For example, TFLC PIC 400 may include waveguides, splitters, bends, mode converters, polarization beam rotators, and/or other optical components used to transmit and/or modify the optical signal carried by TFLC PIC 400. Electrodes may be used in conjunction with waveguide(s), for example for optical modulation (e.g. via the electro-optic effect).

In addition, TFLC PIC 400 includes waveguide 411. In some embodiments, waveguide 411 is a TFLC waveguide. In other embodiments, waveguide 411 may include other and/or additional materials. For simplicity, waveguide 411 is described as a TFLC waveguide. In the embodiment shown, TFLC waveguide 411 is a channel waveguide. Other configurations are possible. For example, TFLC waveguide 411 might include a rib portion and a slab portion or a rib portion, a slab portion, and an intermediate portion. The sidewall angles and waveguide thicknesses may also be in analogous ranges as for waveguides 110/310 of TFLC PIC 100 and/or 300. In addition, the sparsity of the TFLC electro-optic material (e.g. TFLC waveguides 410 and 411) in TFLC PIC 400 may be in analogous ranges as for TFLC PIC 100. TFLC waveguides 410 and 411 have been encapsulated in a manner analogous to TFLC waveguide 110. Thus, in some embodiments, any ends of TFLC waveguides 410 and 411 at edges of TFLC PIC 400 may or may not be covered by another material.

Photonics IC 460 is analogous to ICs 160 and/or 360. In some embodiments, photonics IC 460 is a silicon photonics IC. Photonics IC 460 may have photodetector (PD) 462. PD 462 may include or be formed of III-V materials. Photonics IC 460 may be flip-bonded on a TFLC PIC 400. The optical signal is coupled between TFLC PIC 400 and PD 462 via TFLC waveguide 411. The coupling between TFLC waveguide 411 and PD 462 may be through evanescent coupling, a grating (not shown) or edge coupling if the TFLC electro-optic materials are recessed proximate to an edge. Photonics IC 460 may include other and/or additional components.

Integrated device package 401 functions in an analogous manner to integrated device packages 101, 101D, 101E, 301, 301D, and/or 301E. Integrated devices package 401 may share the benefits of integrated device packages 101, 101D, 101E, 301, 301D, and/or 301E. For example, TFLC PIC 400 may provide optical modulation with losses in the modulation region, data rates, and ability to couple between ICs 400 and 460 as for TFLC PICs 100 and/or 300. In addition, formation of integrated devices package 401 may be completed in an analogous manner to integrated device packages 101, 101D, 101E, 301, 301D, and/or 301E. Thus, manufacturing may also be facilitated. Consequently, both performance and manufacturing of integrated photonic device 401 may be improved. In addition, the use of PD 462 allows for monitoring of the optical signals in TFLC waveguide(s) 410 and 411. Thus, control over integrated photonics package 400 may be improved.

FIG. 5 depicts an embodiment of integrated photonics package 501 incorporating an embodiment of TFLC PIC 500 and photonics IC 560. Other components are generally present but are not shown for clarity. For example, photonics package 501 may include electrical input and output (I/O) and/or optical I/O (e.g., a fiber array unit). Although one TFLC PIC 500 is shown, multiple TFLC PICs and/or multiple additional ICs may be present in particular integrated photonics device packages.

TFLC PIC 500 is analogous to TFLC PIC 100. Analogous components are labeled similarly. TFLC PIC 500 includes TFLC optical component(s) (e.g., TFLC waveguides) 510, electrodes (not shown for clarity), and cladding 550 that may be analogous to TFLC optical component(s) 110/310, electrodes, and cladding 150/350. In the embodiment shown, TFLC waveguide 510 includes a slab portion and a rib portion. Other configurations are possible. For example, TFLC PIC 500 may include waveguides, splitters, bends, mode converters, polarization beam rotators, and/or other optical components used to transmit and/or modify the optical signal carried by TFLC PIC 500. Electrodes may be used in conjunction with waveguide(s), for example for optical modulation (e.g. via the electro-optic effect).

In addition, TFLC PIC 500 includes additional waveguiding layer 580. Additional waveguiding layer 580 may include or consist of a dielectric with optical index of at least 1.5 and not more than 3.6 to assist optical coupling between waveguide 510 and waveguide 570 in IC 560. The additional waveguide layer 580 may be or include one or more of SiN, SiON, titanium dioxide (e. g, TiO₂), and aluminum dioxide (Al₂O₃).

Photonics IC 560 is analogous to ICs 160 and/or 360. In some embodiments, photonics IC 560 is a silicon photonics IC. Photonics IC 560 includes waveguide 570 that is analogous to waveguides 170/370.

Integrated device package 501 functions in an analogous manner to other integrated device packages described herein. Integrated devices package 501 may share the benefits of other integrated device packages described herein. For example, TFLC PIC 500 may provide optical modulation with losses in the modulation region, data rates, and ability to couple between ICs 500 and 560 as described herein. In addition, formation of integrated devices package 501 may be completed in an analogous manner to integrated photonic device packages described herein. Thus, manufacturing may also be facilitated. Consequently, both performance and manufacturing of integrated photonic device 501 may be improved. In addition, the use of additional waveguiding layer 580 may improve the coupling between TFLC PIC 500 and IC 560 (e.g. between waveguide 510 and waveguide 570). Thus, performance of integrated photonics package 500 may be improved.

FIGS. 6A-6B depict embodiments of integrated photonics packages 601A and 601B incorporating an embodiment of TFLC PIC 600A and 600B, respectively, and photonics IC 660. Other components are generally present but are not shown for clarity. For example, photonics package 601A and/or 601B may include electrical input and output (I/O) and/or optical I/O (e.g., a fiber array unit). Although one TFLC PIC 600A/600B is shown in each device 601A and 601B, multiple TFLC PICs and/or multiple additional ICs may be present in particular integrated photonics device packages.

TFLC PIC 600A and 600B are each analogous to TFLC PIC 100 as well as to TFLC PIC 500. Analogous components are labeled similarly. TFLC PICs 600A and 600B each includes TFLC optical component(s) (e.g., TFLC waveguides) 610, electrodes (not shown for clarity), and cladding 650 that may be analogous to TFLC optical component(s) 110/310, electrodes, and cladding 150/350. In the embodiment shown, TFLC waveguide 610 includes a slab portion and a rib portion. Other configurations are possible. For example, TFLC PICs 600A and/or 600B may include waveguides, splitters, bends, mode converters, polarization beam rotators, and/or other optical components used to transmit and/or modify the optical signal carried by TFLC PIC 600A and/or 600B, respectively. Electrodes may be used in conjunction with waveguide(s), for example for optical modulation (e.g. via the electro-optic effect).

In addition, TFLC PICs 600A and 600B each includes additional waveguiding layer 680A and 680B, respectively, that is analogous to additional waveguiding layer 580. Additional waveguiding layers 680A and/or 680B may include or consist of a dielectric with optical index of at least 1.5 and not more than 3.6 to assist optical coupling between waveguide 610 and waveguide 670 in IC 660. The additional waveguide layer 680 may be or include one or more of SiN, SiON, titanium dioxide (e. g, TiO₂), and aluminum dioxide (Al₂O₃). Further, additional waveguiding layers 680A and 680B surround TFLC waveguides 610. In some embodiments, the top portion, bottom portion, and/or one or both side portions of additional waveguiding layer(s) 680 and/or 680B may be omitted.

Photonics IC 660 is analogous to ICs 160 and/or 360. In some embodiments, photonics IC 660 is a silicon photonics IC. Photonics IC 660 includes waveguide 670 that is analogous to waveguides 170/370.

Integrated device packages 601A and 601B function in an analogous manner to other integrated device packages described herein. Integrated devices packages 601A and 601B may share the benefits of other integrated device packages described herein. For example, TFLC PIC(s) 600A and/or 600B may provide optical modulation with losses in the modulation region, data rates, and ability to couple between ICs 600A/600B and 660 as described herein. In addition, formation of integrated devices package(s) 601A and/or 601B may be completed in an analogous manner to integrated photonic device packages described herein. Thus, manufacturing may also be facilitated. Consequently, both performance and manufacturing of integrated photonic device(s) 601A and/or 601B may be improved. In addition, the use of additional waveguiding layer(s) 680A and/or 680B may improve the coupling between TFLC PIC 600A/600B and IC 660 (e.g. between waveguide 610 and waveguide 670). Thus, performance of integrated photonics package 600 may be improved.

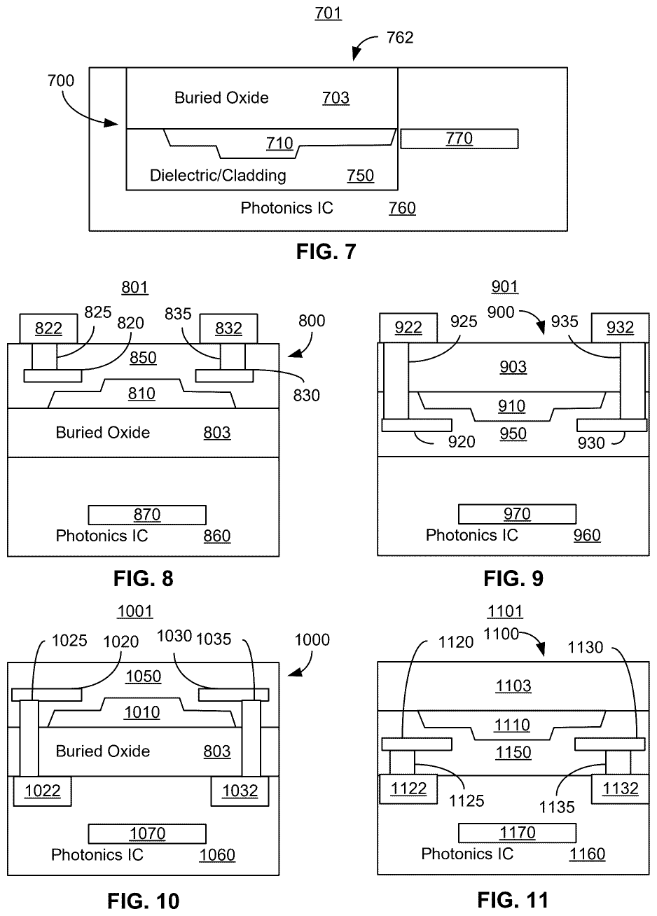

FIG. 7 depicts an embodiment of integrated photonics package 701 incorporating an embodiment of TFLC PIC 700 and photonics IC 760. Other components are generally present but are not shown for clarity. For example, photonics package 701 may include electrical input and output (I/O) and/or optical I/O (e.g., a fiber array unit). Although one TFLC PIC 700 is shown, multiple TFLC PICs and/or multiple additional ICs may be present in particular integrated photonics device packages.

TFLC PIC 700 is analogous to TFLC PIC 100. Analogous components are labeled similarly. TFLC PIC 700 includes TFLC optical component(s) (e.g., TFLC waveguides) 710, electrodes (not shown for clarity), and cladding 750 that may be analogous to TFLC optical component(s) 110/310, electrodes, and cladding 150/350. In the embodiment shown, TFLC waveguide 710 includes a slab portion and a rib portion. Other configurations are possible. For example, TFLC PIC 700 may include waveguides, splitters, bends, mode converters, polarization beam rotators, and/or other optical components used to transmit and/or modify the optical signal carried by TFLC PIC 700. Electrodes may be used in conjunction with waveguide(s), for example for optical modulation (e.g. via the electro-optic effect).

Photonics IC 760 is analogous to ICs 160 and/or 360. In some embodiments, photonics IC 760 is a silicon photonics IC. Photonics IC 760 includes waveguide 770 that is analogous to waveguides 170/370. Photonics IC 760 also includes recess 762 in which TFLC PIC 700 is configured to fit. Although no space is shown between the edges of TFLC PIC 700 and photonics IC 760, in some embodiments, space below and/or to the side(s) of TFLC PIC 700 may be present. However, waveguide 770 is edge coupled with TFLC waveguide 710. In some embodiments, therefore, the space between the edge of TFLC waveguide 710 and waveguide 770 is desired to be reduced or minimized and the alignment optimized. In the embodiment shown, the slab portion of TFLC waveguide 710 has been extended to facilitate optical coupling between TFLC waveguide 710 and waveguide 770. In some embodiments, waveguide(s) 710 and/or 770 have mode converters to improve their optical coupling.

Integrated device package 701 functions in an analogous manner to other integrated device packages described herein. Integrated devices package 701 may share the benefits of other integrated device packages described herein. For example, TFLC PIC 700 may provide optical modulation with losses in the modulation region, data rates, and ability to couple between ICs 700 and 760 as described herein. In addition, formation of integrated devices package 701 may be completed in an analogous manner to integrated photonic device packages described herein. Thus, manufacturing may also be facilitated. Consequently, both performance and manufacturing of integrated photonic device 701 may be improved. In addition, the use of recess 762 may facilitate integration of TFLC PIC 700 and IC 760.

FIG. 8 depicts an embodiment of integrated photonics package 801 incorporating an embodiment of TFLC PIC 800 and photonics IC 860. Other components are generally present but are not shown for clarity. For example, photonics package 801 may include electrical input and output (I/O) and/or optical I/O (e.g., a fiber array unit). Although one TFLC PIC 800 is shown, multiple TFLC PICs and/or multiple additional ICs may be present in particular integrated photonics device packages.

TFLC PIC 800 is analogous to TFLC PIC 100. Analogous components are labeled similarly. TFLC PIC 800 includes TFLC optical component(s) (e.g., TFLC waveguides) 810, electrodes, and cladding 850 that may be analogous to TFLC optical component(s) 110/310, electrodes, and cladding 150/350. In the embodiment shown, TFLC waveguide 810 includes a slab portion and a rib portion. Other configurations are possible. For example, TFLC PIC 800 may include waveguides, splitters, bends, mode converters, polarization beam rotators, and/or other optical components used to transmit and/or modify the optical signal carried by TFLC PIC 800. Electrodes may be used in conjunction with waveguide(s), for example for optical modulation (e.g. via the electro-optic effect).

In addition, TFLC PIC 800 explicitly includes electrodes 820 and 830. In some embodiments, electrodes 820 and 830 are analogous to extensions 224 and 324, respectively. Also shown are channel regions 822 and 832 that are analogous to channel regions 222 and 232, respectively. Channel regions 822 and 832 are coupled to electrodes/extensions 820 and 830, respectively, by conductive vias 825 and 835, respectively. Consequently, channel regions 822 and 832 may be further from TFLC waveguide 810. Thus, microwave losses may be mitigated. In other embodiments, structures 822 and 832 may be conductive pads, while extensions 820 and 830 may form continuous electrodes. Extensions/electrodes 822 and 832 are formed during fabrication of TFLC PIC (e.g., before integration of TFLC PIC 800 with IC 860). Conductive vias 825 and 835 may be formed by etching through cladding 850 to expose extensions 820 and 830, then partially or completely filling the vias. Channel regions 822 and 832 may then be formed. Because TFLC waveguide 810 sparsely occupies the footprint of TFLC PIC 800, formation of vias 825 and 835 may be simplified. In some embodiments, conductive vias 825 and/or 835 may be formed after integration of TFLC PIC 800 with IC 860. In other embodiments, conductive vias 825 and/or 835 may be formed during fabrication of TFLC PIC 800. Similarly, channel regions 822 and 832 may be formed after integration of TFLC PIC 800 with IC 860 or during fabrication of TFLC PIC 800. Although shown as being on the top surface of cladding 850, in some embodiments, channel regions 822 and 832 may be in recesses in cladding 850. Moreover, extensions/electrodes 820 and 830, conductive vias 825 and 835, and channel regions/pads 822 and 832 may allow for differential driving of TFLC waveguide 810. Thus, TFLC PIC 800 may be driven by lower voltages.

Photonics IC 860 is analogous to ICs 160 and/or 360. In some embodiments, photonics IC 860 is a silicon photonics IC. Photonics IC 860 includes waveguide 870 that is analogous to waveguides 170/370.

Integrated device package 801 functions in an analogous manner to other integrated device packages described herein. Integrated devices package 801 may share the benefits of other integrated device packages described herein. For example, TFLC PIC 800 may provide optical modulation with losses in the modulation region, data rates, and ability to couple between ICs 800 and 860 as described herein. In addition, formation of integrated devices package 801 may be completed in an analogous manner to integrated photonic device packages described herein. Thus, manufacturing may also be facilitated. Consequently, both performance and manufacturing of integrated photonic device 801 may be improved. In addition, extensions/electrodes 820 and 830, conductive vias 825 and 835, and channel regions/pads 822 and 832 may not only facilitate fabrication of integrated photonics device 801, but also improve performance.

FIG. 9 depicts an embodiment of integrated photonics package 901 incorporating an embodiment of TFLC PIC 900 and photonics IC 960. Other components are generally present but are not shown for clarity. For example, photonics package 901 may include electrical input and output (I/O) and/or optical I/O (e.g., a fiber array unit). Although one TFLC PIC 900 is shown, multiple TFLC PICs and/or multiple additional ICs may be present in particular integrated photonics device packages.

TFLC PIC 900 is analogous to TFLC PIC 100 and TFLC PIC 800. However, TFLC PIC 900 has been flip chip bonded to IC 960. Analogous components are labeled similarly. TFLC PIC 900 includes TFLC optical component(s) (e.g., TFLC waveguides) 910, electrodes, and cladding 950 that may be analogous to TFLC optical component(s) 110/310, electrodes, and cladding 150/350. In the embodiment shown, TFLC waveguide 910 includes a slab portion and a rib portion. Other configurations are possible. For example, TFLC PIC 900 may include waveguides, splitters, bends, mode converters, polarization beam rotators, and/or other optical components used to transmit and/or modify the optical signal carried by TFLC PIC 900. Electrodes may be used in conjunction with waveguide(s), for example for optical modulation (e.g. via the electro-optic effect).

In addition, TFLC PIC 900 explicitly includes electrodes 920 and 930. In some embodiments, electrodes 920 and 930 are analogous to extensions 224 and 324, respectively. Also shown are channel regions 922 and 932 that are analogous to channel regions 222 and 232, respectively. Channel regions 922 and 932 are coupled to electrodes/extensions 920 and 930, respectively, by conductive vias 925 and 935, respectively. Conductive vias 925 and 935 extend through BOX layer 903. Consequently, channel regions 922 and 932 may be further from TFLC waveguide 910. Thus, microwave losses may be mitigated. In other embodiments, structures 922 and 932 may be conductive pads, while extensions 920 and 930 may form continuous electrodes. Extensions/electrodes 922 and 932 are formed during fabrication of TFLC PIC (e.g., before integration of TFLC PIC 900 with IC 960). Conductive vias 925 and 935 may be formed by etching through BOX layer 903 to expose extensions 920 and 930, then partially or completely filling the vias. Thus, conductive vias 925 and 935 extend past waveguide 910 in some embodiments. Channel regions 922 and 932 may then be formed. Thus, conductive vias may be formed after completion of TFLC PIC 900 and after removal of the corresponding substrate (not shown in FIG. 9). Because TFLC waveguide 910 sparsely occupies the footprint of TFLC PIC 900, formation of vias 925 and 935 may be simplified. In some embodiments, conductive vias 925 and/or 935 may be formed after integration of TFLC PIC 900 with IC 960. In other embodiments, conductive vias 925 and/or 935 may be formed during fabrication of TFLC PIC 900. Similarly, channel regions 922 and 932 may be formed after integration of TFLC PIC 900 with IC 960. Although shown as being on the top surface of BOX layer 903, in some embodiments, channel regions 922 and 932 may be in recesses in BOX layer 903. Moreover, extensions/electrodes 920 and 930, conductive vias 925 and 935, and channel regions/pads 922 and 932 may allow for differential driving of TFLC waveguide 910. Thus, TFLC PIC 900 may be driven by lower voltages.

Photonics IC 960 is analogous to ICs 160 and/or 360. In some embodiments, photonics IC 960 is a silicon photonics IC. Photonics IC 960 includes waveguide 970 that is analogous to waveguides 170/370.

Integrated device package 901 functions in an analogous manner to other integrated device packages described herein. Integrated devices package 901 may share the benefits of other integrated device packages described herein. For example, TFLC PIC 900 may provide optical modulation with losses in the modulation region, data rates, and ability to couple between ICs 900 and 960 as described herein. In addition, formation of integrated devices package 901 may be completed in an analogous manner to integrated photonic device packages described herein. Thus, manufacturing may also be facilitated. Consequently, both performance and manufacturing of integrated photonic device 901 may be improved. In addition, extensions/electrodes 920 and 930, conductive vias 925 and 935, and channel regions/pads 922 and 932 may not only facilitate fabrication of integrated photonics device 901, but also improve performance.

FIG. 10 depicts an embodiment of integrated photonics package 1001 incorporating an embodiment of TFLC PIC 1000 and photonics IC 1060. Other components are generally present but are not shown for clarity. For example, photonics package 1001 may include electrical input and output (I/O) and/or optical I/O (e.g., a fiber array unit). Although one TFLC PIC 1000 is shown, multiple TFLC PICs and/or multiple additional ICs may be present in particular integrated photonics device packages.

TFLC PIC 1000 is analogous to TFLC PIC 100 and TFLC PIC 800. Analogous components are labeled similarly. TFLC PIC 1000 includes TFLC optical component(s) (e.g., TFLC waveguides) 1010, electrodes, and cladding 1050 that may be analogous to TFLC optical component(s) 110/310, electrodes, and cladding 150/350. In the embodiment shown, TFLC waveguide 1010 includes a slab portion and a rib portion. Other configurations are possible. For example, TFLC PIC 1000 may include waveguides, splitters, bends, mode converters, polarization beam rotators, and/or other optical components used to transmit and/or modify the optical signal carried by TFLC PIC 1000. Electrodes may be used in conjunction with waveguide(s), for example for optical modulation (e.g. via the electro-optic effect).

In addition, TFLC PIC 1000 explicitly includes electrodes 1020 and 1030. In some embodiments, electrodes 1020 and 1030 are analogous to extensions 224 and 324, respectively. Also shown are channel regions 1022 and 1032 that are analogous to channel regions 222 and 232, respectively. Channel regions 1022 and 1032 are coupled to electrodes/extensions 1020 and 1030, respectively, by conductive vias 1025 and 1035, respectively. Conductive vias 1025 and 1035 extend through BOX layer 1003 and through a portion of cladding 1050. Consequently, channel regions 1022 and 1032 may be further from TFLC waveguide 1010. Thus, microwave losses may be mitigated. In other embodiments, structures 1022 and 1032 may be conductive pads, while extensions 1020 and 1030 may form continuous electrodes. Extensions/electrodes 1022 and 1032 are formed during fabrication of TFLC PIC (e.g., before integration of TFLC PIC 1000 with IC 1060). Conductive vias 1025 and 1035 may be formed by etching through BOX layer 1003 and a portion of cladding 1050 to expose extensions 1020 and 1030, then partially or completely filling the vias. Thus, conductive vias may be formed after completion of TFLC PIC 1000 and after removal of the corresponding substrate (not shown in FIG. 10). Because TFLC waveguide 1010 sparsely occupies the footprint of TFLC PIC 1000, formation of vias 1025 and 1035 may be simplified. In some embodiments, conductive vias 1025 and/or 1035 may be formed during fabrication of TFLC PIC 1000, for example after removal of the substrate (not shown). Channel regions 1022 and 1032 may be formed during fabrication of photonics IC 1060. Moreover, extensions/electrodes 1020 and 1030, conductive vias 1025 and 1035, and channel regions/pads 1022 and 1032 may allow for differential driving of TFLC waveguide 1010. Thus, TFLC PIC 1000 may be driven by lower voltages.

Photonics IC 1060 is analogous to ICs 160 and/or 360. In some embodiments, photonics IC 1060 is a silicon photonics IC. Photonics IC 1060 includes waveguide 1070 that is analogous to waveguides 170/370. Channel regions 1022 and 1032 may be formed as part of fabrication of photonics IC 1060. For example, recesses may be formed in photonics IC 1060 and the recesses filled with conductive material. In some embodiments, conductive channel regions 1022 and 1032 may be deposited, an insulating layer deposited on IC 1060, and the top surface planarized, exposing channel regions 1022 and 1032. Other techniques may be used in some embodiments.

Integrated device package 1001 functions in an analogous manner to other integrated device packages described herein. Integrated devices package 1001 may share the benefits of other integrated device packages described herein. For example, TFLC PIC 1000 may provide optical modulation with losses in the modulation region, data rates, and ability to couple between ICs 1000 and 1060 as described herein. In addition, formation of integrated devices package 1001 may be completed in an analogous manner to integrated photonic device packages described herein. Thus, manufacturing may also be facilitated. Consequently, both performance and manufacturing of integrated photonic device 1001 may be improved. In addition, extensions/electrodes 1020 and 1030, conductive vias 1025 and 1035, and channel regions/pads 1022 and 1032 may not only facilitate fabrication of integrated photonics device 1001, but also improve performance.

FIG. 11 depicts an embodiment of integrated photonics package 1101 incorporating an embodiment of TFLC PIC 1100 and photonics IC 1160. Other components are generally present but are not shown for clarity. For example, photonics package 1101 may include electrical input and output (I/O) and/or optical I/O (e.g., a fiber array unit). Although one TFLC PIC 1100 is shown, multiple TFLC PICs and/or multiple additional ICs may be present in particular integrated photonics device packages.

TFLC PIC 1100 is analogous to TFLC PIC 100 and TFLC PIC 800. However, TFLC PIC 1100 has been flip chip bonded to IC 1160. Analogous components are labeled similarly. TFLC PIC 1100 includes TFLC optical component(s) (e.g., TFLC waveguides) 1110, electrodes, and cladding 1150 that may be analogous to TFLC optical component(s) 110/310, electrodes, and cladding 150/350. In the embodiment shown, TFLC waveguide 1110 includes a slab portion and a rib portion. Other configurations are possible. For example, TFLC PIC 1100 may include waveguides, splitters, bends, mode converters, polarization beam rotators, and/or other optical components used to transmit and/or modify the optical signal carried by TFLC PIC 1100. Electrodes may be used in conjunction with waveguide(s), for example for optical modulation (e.g. via the electro-optic effect).

TFLC PIC 1100 explicitly includes electrodes 1120 and 1130. In some embodiments, electrodes 1120 and 1130 are analogous to extensions 224 and 324, respectively. Also shown are channel regions 1122 and 1132 that are analogous to channel regions 222 and 232, respectively. Channel regions 1122 and 1132 are coupled to electrodes/extensions 1120 and 1130, respectively, by conductive vias 1125 and 1135, respectively. Conductive vias 1125 and 1135 extend through cladding 1150. Consequently, channel regions 1122 and 1132 may be further from TFLC waveguide 1110. Thus, microwave losses may be mitigated. In other embodiments, structures 1122 and 1132 may be conductive pads, while extensions 1120 and 1130 may form continuous electrodes. Extensions/electrodes 1122 and 1132 are formed during fabrication of TFLC PIC (e.g., before integration of TFLC PIC 1100 with IC 1160). Conductive vias 1125 and 1135 may be formed by etching through a portion of cladding 1150 to expose extensions 1120 and 1130, then partially or completely filling the vias. Because TFLC waveguide 1110 sparsely occupies the footprint of TFLC PIC 1100, formation of vias 1125 and 1135 may be simplified. In some embodiments, conductive vias 1125 and/or 1135 may be formed during fabrication of TFLC PIC 1100. Channel regions 1122 and 1132 may be formed during fabrication of photonics IC 1160. Moreover, extensions/electrodes 1120 and 1130, conductive vias 1125 and 1135, and channel regions/pads 1122 and 1132 may allow for differential driving of TFLC waveguide 1110. Thus, TFLC PIC 1100 may be driven by lower voltages.

Photonics IC 1160 is analogous to ICs 160 and/or 360. In some embodiments, photonics IC 1160 is a silicon photonics IC. Photonics IC 1160 includes waveguide 1170 that is analogous to waveguides 170/370. Channel regions 1122 and 1132 may be formed as part of fabrication of photonics IC 1160. For example, recesses may be formed in photonics IC 1160 and the recesses filled with conductive material. In some embodiments, conductive channel regions 1122 and 1132 may be deposited, an insulating layer deposited on IC 1060, and the top surface planarized, exposing channel regions 1122 and 1132. Other techniques may be used in some embodiments.

Integrated device package 1101 functions in an analogous manner to other integrated device packages described herein. Integrated devices package 1101 may share the benefits of other integrated device packages described herein. For example, TFLC PIC 1100 may provide optical modulation with losses in the modulation region, data rates, and ability to couple between ICs 1100 and 1160 as described herein. In addition, formation of integrated devices package 1101 may be completed in an analogous manner to integrated photonic device packages described herein. Thus, manufacturing may also be facilitated. Consequently, both performance and manufacturing of integrated photonic device 1101 may be improved. In addition, extensions/electrodes 1120 and 1130, conductive vias 1125 and 1135, and channel regions/pads 1122 and 1132 may not only facilitate fabrication of integrated photonics device 1101, but also improve performance.

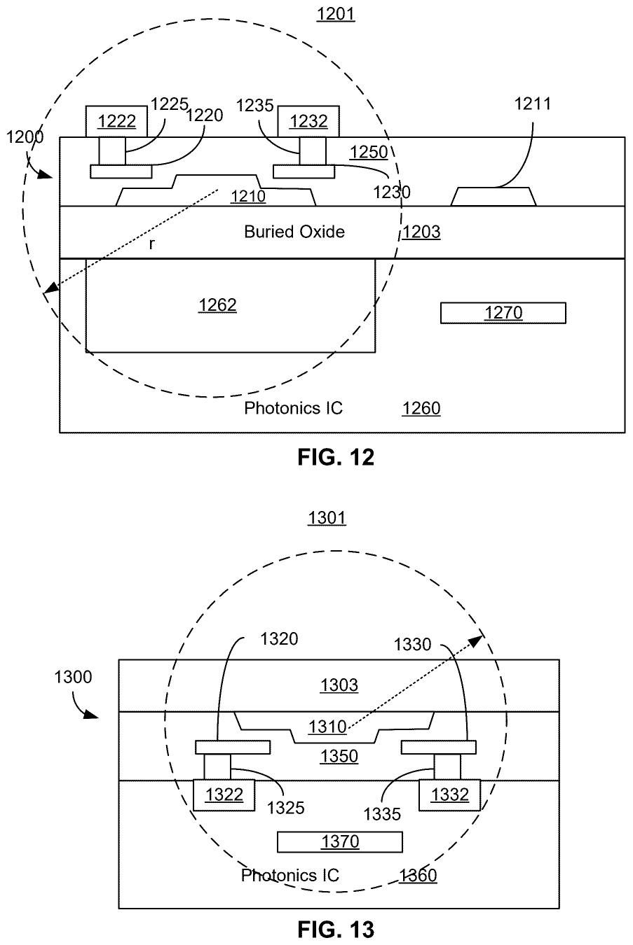

FIG. 12 depicts an embodiment of integrated photonics package 1201 incorporating an embodiment of TFLC PIC 1200 and photonics IC 1260. Other components are generally present but are not shown for clarity. For example, photonics package 1201 may include electrical input and output (I/O) and/or optical I/O (e.g., a fiber array unit). Although one TFLC PIC 1200 is shown, multiple TFLC PICs and/or multiple additional ICs may be present in particular integrated photonics device packages.

TFLC PIC 1200 is analogous to TFLC PIC 100 and TFLC PIC 800. Analogous components are labeled similarly. TFLC PIC 1200 includes TFLC optical component(s) (e.g., TFLC waveguides) 1210, electrodes, and cladding 1250 residing that may be analogous to TFLC optical component(s) 110/310, electrodes, and cladding 150/350. In the embodiment shown, TFLC waveguide 1210 includes a slab portion and a rib portion. Other configurations are possible. For example, TFLC PIC 1200 may include waveguides, splitters, bends, mode converters, polarization beam rotators, and/or other optical components used to transmit and/or modify the optical signal carried by TFLC PIC 1200. Electrodes may be used in conjunction with waveguide(s), for example for optical modulation (e.g. via the electro-optic effect).

TFLC PIC 1200 explicitly includes electrodes 1220 and 1230. In some embodiments, electrodes 1220 and 1230 are analogous to extensions 820 and 830, respectively. Also shown are channel regions 1222 and 1232 that are analogous to channel regions 822 and 832, respectively. Channel regions 1222 and 1232 are coupled to electrodes/extensions 1220 and 1230, respectively, by conductive vias 1225 and 1235, respectively. Conductive vias 1225 and 1235 are analogous to conductive vias 825 and 835, respectively. Extensions/electrodes 1220 and 1230, conductive vias 1225 and 1235, and channel regions/pads 1222 and 1232 may allow for differential driving of TFLC waveguide 1210. Thus, TFLC PIC 1200 may be driven by lower voltages. TFLC PIC 1200 also includes additional waveguide 1211 that may be analogous to TFLC waveguide 411 or additional waveguiding layer 580.

Photonics IC 1260 is analogous to ICs 160, 360 and/or 760. In some embodiments, photonics IC 1260 is a silicon photonics IC. Photonics IC 1260 includes waveguide 1270 that is analogous to waveguides 170/370/770. Photonics IC 1260 also includes void 1262 that is analogous to recess 762. However, void 1262 is not configured to fit TFLC PIC 1200 therein. Instead, void 1262 may be used to reduce microwave losses. In some embodiments, void 1262 may be evacuated or filled with air. In some embodiments, void 1262 may include other materials that mitigate microwave losses.

For example, void 1262 may be used to tailor the microwave dielectric index of integrated a region of photonics package 1201. In some embodiments, the average microwave dielectric index at a particular frequency is corporates the microwave dielectric indexes of all non-metallic portions of integrated photonics package 1201 in that region. Although termed an average, an average, a median, or other statistical measure of the microwave dielectric index might be used. In some embodiments, the region may be considered to include the areas surrounding integrated photonics package 1201. In some embodiments, the region is a volume within a particular radius, r, of a portion (e.g. the central axis) of TFLC waveguide 1210. This region is indicated by a dashed line in FIG. 12. In some embodiments, integrated photonics device 1200 is configured such that at a frequency of 100 GHz the average microwave dielectric index within a twenty micrometer radius centered at the TFLC waveguide 1210 (e.g., r=20 micrometers) is less than 10. In some embodiments, this average microwave dielectric index is less than 7. In some embodiments, this average microwave dielectric index is less than 5. In some embodiments, this average microwave dielectric index is less than 3. In some embodiments, this average microwave dielectric index is less than 2.7. In some embodiments, this average microwave dielectric index is at least one. In some embodiments, void 1262 may be configured to aid in providing such an average microwave dielectric index. Thus, microwave losses may be mitigated. For other microwave dielectric indexes, void 1262 may still be used to reduce microwave losses.

Integrated device package 1201 functions in an analogous manner to other integrated device packages described herein. Integrated devices package 1201 may share the benefits of other integrated device packages described herein. For example, TFLC PIC 1200 may provide optical modulation with losses in the modulation region, data rates, and ability to couple between ICs 1200 and 1260 as described herein. In addition, formation of integrated devices package 1201 may be completed in an analogous manner to integrated photonic device packages described herein. Thus, manufacturing may also be facilitated. Consequently, both performance and manufacturing of integrated photonic device 1201 may be improved. In addition, extensions/electrodes 1220 and 1230, conductive vias 1225 and 1235, and channel regions/pads 1222 and 1232 may not only facilitate fabrication of integrated photonics device 1201, but also improve performance. Void 1262 may also be used to mitigate microwave losses.

FIG. 13 depicts an embodiment of integrated photonics package 1301 incorporating an embodiment of TFLC PIC 1300 and photonics IC 1360. Other components are generally present but are not shown for clarity. For example, photonics package 1301 may include electrical input and output (I/O) and/or optical I/O (e.g., a fiber array unit). Although one TFLC PIC 1300 is shown, multiple TFLC PICs and/or multiple additional ICs may be present in particular integrated photonics device packages.

TFLC PIC 1300 is analogous to TFLC PIC 100 and TFLC PIC 1100. Analogous components are labeled similarly. TFLC PIC 1300 includes TFLC optical component(s) (e.g., TFLC waveguides) 1310, electrodes, and cladding 1350 that may be analogous to TFLC optical component(s) 110/1110, electrodes, and cladding 150/1150. In the embodiment shown, TFLC waveguide 1310 includes a slab portion and a rib portion. Other configurations are possible. For example, TFLC PIC 1300 may include waveguides, splitters, bends, mode converters, polarization beam rotators, and/or other optical components used to transmit and/or modify the optical signal carried by TFLC PIC 1300. Electrodes may be used in conjunction with waveguide(s), for example for optical modulation (e.g. via the electro-optic effect).

TFLC PIC 1300 explicitly includes electrodes 1320 and 1330. In some embodiments, electrodes 1320 and 1330 are analogous to extensions 1120 and 1130, respectively. Also shown are channel regions 1322 and 1332 that are analogous to channel regions 1122 and 1132, respectively. Channel regions 1322 and 1332 are coupled to electrodes/extensions 1320 and 1330, respectively, by conductive vias 1325 and 1335, respectively. Conductive vias 1325 and 1335 are analogous to conductive vias 1125 and 1135, respectively. Extensions/electrodes 1320 and 1330, conductive vias 1325 and 1335, and channel regions/pads 1322 and 1332 may allow for differential driving of TFLC waveguide 1310. Thus, TFLC PIC 1300 may be driven by lower voltages. TFLC PIC 1300 also includes additional waveguide 1311 that may be analogous to TFLC waveguide 411 or additional waveguiding layer 580.

Photonics IC 1360 is analogous to ICs 160, 360 and/or 1160. In some embodiments, photonics IC 1360 is a silicon photonics IC. Photonics IC 1360 includes waveguide 1370 that is analogous to waveguides 170/370/1170.

In some embodiments, the portion of integrated photonics package 1301 has an average microwave dielectric index analogous to that of integrated photonics package 1201. In some embodiments, average microwave dielectric index in a region within a particular radius, r, of a portion (e.g. the central axis) of TFLC waveguide 1310 (indicated by a dashed line in FIG. 13) has a microwave dielectric index in the ranges discussed with respect to integrated photonics package 1201. In some embodiments, integrated photonics device 1300 is configured such that at a frequency of 100 GHz the average microwave dielectric index within a twenty micrometer radius centered at the TFLC waveguide 1310 (e.g., r=20 micrometers) is less than 10, less than 7, less than 5, less than 3, or less than 2.7. In some embodiments, this average microwave dielectric index is at least one. This may be accomplished by appropriate selection of materials and geometry for cladding 1350, the portions of photonics IC 1360 within this region, and/or other materials within this region.

Integrated device package 1301 functions in an analogous manner to other integrated device packages described herein. Integrated devices package 1301 may share the benefits of other integrated device packages described herein. For example, TFLC PIC 1300 may provide optical modulation with losses in the modulation region, data rates, and ability to couple between ICs 1300 and 1360 as described herein. In addition, formation of integrated devices package 1301 may be completed in an analogous manner to integrated photonic device packages described herein. Thus, manufacturing may also be facilitated. Consequently, both performance and manufacturing of integrated photonic device 1301 may be improved. In addition, extensions/electrodes 1320 and 1330, conductive vias 1325 and 1335, and channel regions/pads 1322 and 1332 may not only facilitate fabrication of integrated photonics device 1301, but also improve performance. Further, microwave losses may be reduced by appropriate configuration of a region within integrated photonics device 1301.

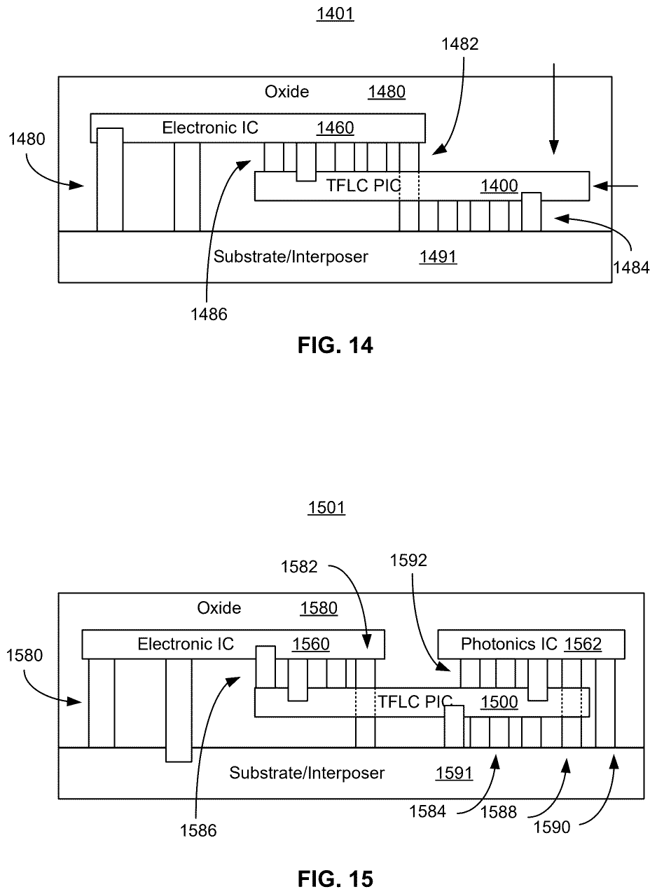

FIG. 14 depicts an embodiment of integrated photonics package 1401 incorporating an embodiment of TFLC PIC 1400 and IC 1460. Other components are generally present but are not shown for clarity. For example, photonics package 1401 may include electrical input and output (I/O) and/or optical I/O (e.g., a fiber array unit). Although one TFLC PIC 1400 is shown, multiple TFLC PICs and/or multiple additional ICs may be present in particular integrated photonics device packages. Also shown is interposer 1491 which mechanically and electrically connects TFLC PIC 1400 with electronic IC 1460.

TFLC PIC 1400 is analogous to TFLC PIC 100 and TFLC PIC 300. For example, TFLC PIC 1400 may be an optical digital to analog converter (ODAC). Analogous components are labeled similarly. TFLC PIC 1400 includes TFLC optical component(s), electrodes, and cladding (all of which are not shown for clarity) that may be analogous to TFLC optical component(s) 110/310, electrodes, and cladding 150/350. For example, TFLC PIC 1400 may include waveguides, splitters, bends, mode converters, polarization beam rotators, and/or other optical components used to transmit and/or modify the optical signal carried by TFLC PIC 1400. In some embodiments, optical signals may be input to TFLC PIC 1400 through edge coupling or vertical coupling (shown by unlabeled arrows in FIG. 14).

IC 1460 is analogous to ICs 160 and/or 360. In some embodiments, IC 1460 is an EIC. EIC 1460 may include drivers, receivers, and/or other electronics used in controlling and/or driving TFLC IC 1400.

Interposer 1491 may be a substrate that may have passive and/or active electrical components incorporated therein. Interposer 1491 is used to mechanically and/or electrically couple EIC 1460 and TFLC PIC 1400. Interposer 1491 may be silicon interposer or an organic interposer. For example, such an interposer 1491 includes organic material(s), such as polyimide, epoxy, laminates, and/or other materials that may be analogous to those used in printed circuit boards (PCBs). Other materials, such as glass might be used for interposer 1491 in some embodiments. EIC 1460 and TFLC PIC 1400 are connected to interposer through conductive vias 1480 and 1484 (only some of which are labeled), respectively. In some embodiments, TFLC PIC 1400 is electrically connected to EIC 1460 through interposer 1491. In some embodiments, TFLC PIC 1400 may be directly connected to EIC 1460 through conductive vias 1486 (only some of which are labeled). Further EIC 1460 may be connected directly to interposer 1491 using conductive via 1482. For example, conductive via 1482 may be or include a through silicon via (TSV). In some embodiments, conductive vias 1480, 1482, 1484, and/or 1486 are connected to pads or other conductive structures on the surfaces of EIC 1460 and/or TFLC PIC 1400. In some embodiments, one or more conductive vias may connect directly to a structure within EIC 1460 and/or TFLC PIC 1400. This is shown by some conductive vias extending past the surface of EIC 1460 and TFLC PIC 1400. Similarly, conductive vias 1480, 1482, and/or 1484 may connected to conductive pads on a surface of interposer 1491 or to a conductive structure within interposer 1491. This is shown by some conductive vias extending past the surface of interposer 1491. In other embodiments, IC 1460 and/or TFLC PIC 1400 are electrically connected to interposer 1491 through solder bumps and/or wire bonds.

Interposer 1491 may include electrical interconnects, for example in one or more redistribution layers (RDLs). For example, electrical signals from IC(s) 1460 may be provided to interposer 1491 via solder bump connections, be routed through interposer 1491 via RDL(s), and provided to TFLC PIC 1400 from interposer 1491 via solder bump and/or wire bond connections. In some embodiments, interposer 1491 is mechanically robust. For example, interposer 1491 may have a thickness of at least three hundred micrometers through not more than 20 millimeters. In some embodiments, interposer 1491 has a thickness of at least one hundred micrometers. The thickness of interposer 1491 may be less than four millimeters or less than two millimeters. In some embodiments, interposer 1491 has a thickness of not more than two hundred micrometers.

Integrated photonics device package 1401 functions in an analogous manner to other integrated device packages described herein. Integrated devices package 1401 may share the benefits of other integrated device packages described herein. For example, TFLC PIC 1400 may provide optical modulation with losses in the modulation region, data rates, and ability to couple between ICs 1400 and 1460 as described herein. In addition, formation of integrated devices package 1401 may be completed in an analogous manner to integrated photonic device packages described herein. Thus, manufacturing may also be facilitated. Consequently, both performance and manufacturing of integrated photonic device 1401 may be improved. In addition, the mechanical robustness of integrated photonics device package 1401 and complexity of the electrical circuitry may be enhanced through the use of interposer 1491. Thus, performance may be improved.

FIG. 15 depicts an embodiment of integrated photonics package 1501 incorporating an embodiment of TFLC PIC 1500 and IC 1560. Other components are generally present but are not shown for clarity. For example, photonics package 1501 may include electrical input and output (I/O) and/or optical I/O (e.g., a fiber array unit). Although one TFLC PIC 1500 is shown, multiple TFLC PICs and/or multiple additional ICs may be present in particular integrated photonics device packages. Also shown is interposer 1591 which mechanically and electrically connects TFLC PIC 1500 with electronic IC 1560.

TFLC PIC 1500 is analogous to TFLC PIC 100 and TFLC PIC 300. For example, TFLC PIC 1500 may be an optical digital to analog converter (ODAC). Analogous components are labeled similarly. TFLC PIC 1500 includes TFLC optical component(s), electrodes, and cladding 1550 (all of which are not shown for clarity) that may be analogous to TFLC optical component(s) 110/310, electrodes, and cladding 150/350. For example, TFLC PIC 1500 may include waveguides, splitters, bends, mode converters, polarization beam rotators, and/or other optical components used to transmit and/or modify the optical signal carried by TFLC PIC 1500. In some embodiments, optical signals may be input to TFLC PIC 1500 through edge coupling or vertical coupling.

IC 1560 is analogous to ICs 160, 360 and/or 1460. In some embodiments, IC 1560 is an EIC. EIC 1560 may include drivers, receivers, and/or other electronics used in controlling and/or driving TFLC IC 1500. Also shown is photonics IC 1562. Photonics IC 1562 is analogous to other photonics ICs described herein.

Interposer 1591 is analogous to interposer 1491. Thus, interposer 1591 provides mechanical, electrical, and in some embodiments optical, coupling between ICs 1500, 1560, and 1562. Also shown are conductive vias 1580, 1582, 1584, 1586, 1588, 1590, and 1592 that are analogous to conductive vias 1480, 1482, 1484, and 1486. Conductive vias 1580, 1582, 1584, 1586, 1588, 1590, and 1592 interconnect EIC 1560, Photonics IC 1562, TFLC PIC 1500, and/or interposer 1591.

Integrated photonics device package 1501 functions in an analogous manner to other integrated device packages described herein. Integrated devices package 1501 may share the benefits of other integrated device packages described herein. For example, TFLC PIC 1500 may provide optical modulation with losses in the modulation region, data rates, and ability to couple between ICs 1500, 1560, and 1562 as described herein. Further, larger numbers of ICs (e.g. three or more) may be packaged together. In addition, formation of integrated devices package 1501 may be completed in an analogous manner to integrated photonic device packages described herein. Thus, manufacturing may also be facilitated. Consequently, both performance and manufacturing of integrated photonic device 1501 may be improved. In addition, the mechanical robustness of integrated photonics device package 1501 and complexity of the electrical circuitry may be enhanced through the use of interposer 1591. Thus, performance may be improved.

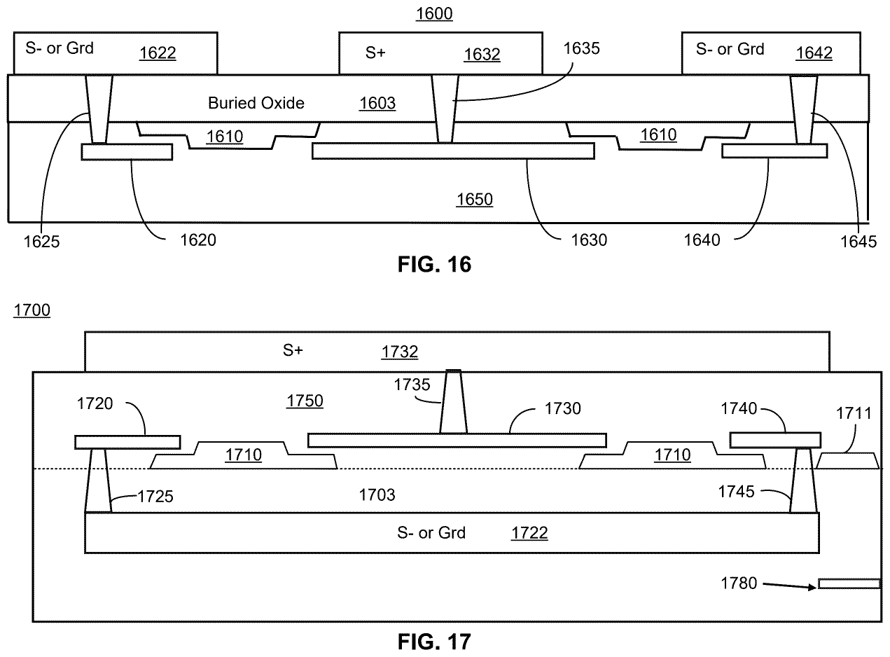

FIG. 16 depicts an embodiment of TFLC PIC 1600 usable in an embodiment of an integrated photonics package. Other components are generally present but are not shown for clarity. For example, TFLC PIC 1600 may include electrical input and output (I/O) and/or optical I/O (e.g., a fiber array unit). TFLC PIC 1600 is depicted as flipped, for example prior to flip-chip bonding.

TFLC PIC 1600 is analogous to TFLC PIC 100. Analogous components are labeled similarly. TFLC PIC 1600 includes TFLC optical component(s) (e.g., TFLC waveguides) 1610, electrodes, and cladding 1650 that may be analogous to TFLC optical component(s) 110/310, electrodes, and cladding 150/350. In the embodiment shown, TFLC waveguides 1610 each includes a slab portion and a rib portion. Other configurations are possible. For example, TFLC PIC 1600 may include waveguides, splitters, bends, mode converters, polarization beam rotators, and/or other optical components used to transmit and/or modify the optical signal carried by TFLC PIC 1600. Electrodes may be used in conjunction with waveguide(s), for example for optical modulation (e.g. via the electro-optic effect).

TFLC PIC 1600 explicitly includes electrodes 1620, 1630, and 1640. In some embodiments, electrodes 1620, 1630, and 1640 are analogous to extensions 224 and 324. Also shown are channel regions 1622, 1632, and 1642 that are analogous to channel regions 222 and 232. Channel regions 1622, 1632, and 1642 are coupled to electrodes/extensions 1620, 1630, and 1640, respectively, by conductive vias 1625, 1635, and 1645, respectively. Consequently, channel regions 1622, 1632, and 1642 may be further from TFLC waveguide 1610. Thus, microwave losses may be mitigated. In other embodiments, structures 1622, 1632, and 1642 may be conductive pads, while extensions 1620, 1630, and 1640 may form continuous electrodes.

Extensions/electrodes 1620, 1630, and 1640 may be formed during fabrication of TFLC PIC 1600. Conductive vias 1625, 1635, and 1645 may be formed by etching through BOX layer 1603 and a portion of cladding 1650 to expose extensions 1620, 1630, and 1640, then partially or completely filling the vias. In some embodiments, conductive vias 1625, 1635, and 1645 are formed after the substrate (not shown) has been removed and, in some embodiments, BOX layer 1603 has been thinned to the desired thickness. Channel regions 1622, 1632, and 1642 may then be formed.

Because TFLC waveguides 1610 sparsely occupy the footprint of TFLC PIC 1600, formation of conductive vias 1625, 1635, and 1645 may be simplified. In some embodiments, conductive vias 1625, 1635, and/or 1645 and channel regions 1622, 1632, and 1642 may be formed before integration of TFLC PIC 1600 with an IC or interposer via flip-chip bonding. In other embodiments, conductive vias 1625, 1635, and/or 1645 may be formed after integration of TFLC PIC 1600 with an IC or interposer via flip-chip bonding, when the bottom of BOX layer 1603 is exposed. Similarly, channel regions 1622, 1632, and 1642 may be formed after integration of TFLC PIC 1600. Although shown as being on the top surface of BOX layer 1603, in some embodiments, channel regions 1622, 1632, and 1642 may be in recesses in BOX layer 1603. Extensions/electrodes 1620, 1630, and 1640, conductive vias 1625, 1635, and 1645, and channel regions/pads 1622, 1632, and 1642 may allow for differential driving of both TFLC waveguides 1610. Thus, TFLC PIC 1600 may be driven by lower voltages.

TFLC PIC 1600 may be integrated into a photonics device package in an analogous manner to other TFLC PICs described herein. Thus, the benefits described herein may be achieved. Further, push-pull driving of TFLC waveguides may be accomplished. As a result, a lower voltage may be used to drive modulation of the optical signal transmitted by waveguides 1610.

FIG. 17 depicts an embodiment of TFLC PIC 1700 usable in an embodiment of an integrated photonics package. Other components are generally present but are not shown for clarity. For example, TFLC PIC 1700 may include electrical input and output (I/O) and/or optical I/O (e.g., a fiber array unit). TFLC PIC 1700 is shown right side up, in position for bonding to an underlying interposer or IC.

TFLC PIC 1700 is analogous to TFLC PIC 100. Analogous components are labeled similarly. TFLC PIC 1700 includes TFLC optical component(s) (e.g., TFLC waveguides) 1710, electrodes, and cladding 1750 that may be analogous to TFLC optical component(s) 110/310, electrodes, and cladding 150/350. In the embodiment shown, TFLC waveguides 1710 each includes a slab portion and a rib portion. Other configurations are possible. For example, TFLC PIC 1700 may include waveguides, splitters, bends, mode converters, polarization beam rotators, and/or other optical components used to transmit and/or modify the optical signal carried by TFLC PIC 1700. Electrodes may be used in conjunction with waveguide(s), for example for optical modulation (e.g. via the electro-optic effect). TFLC PIC 1700 also includes additional TFLC waveguide 1711 and additional waveguiding layer 1780 that are analogous to additional waveguide 411 and additional waveguiding layer 580.

TFLC PIC 1700 explicitly includes electrodes 1720, 1730, and 1740. In some embodiments, electrodes 1720, 1730, and 1740 are analogous to extensions 224 and 324. Also shown are channel regions 1722 and 1732 that are analogous to channel regions 222 and 232. Thus, extensions 1720 and 1740 share channel region 1722. Channel regions 1722 and 1732 are coupled to electrodes/extensions 1720, 1730, and 1740 by conductive vias 1725, 1735, and 1745, respectively. Consequently, channel regions 1722 and 1732 may be further from TFLC waveguide 1710. Thus, microwave losses may be mitigated. In other embodiments, structures 1722 and 1732 may be conductive pads, while extensions 1720, 1730, and 1740 may form continuous electrodes.

Extensions/electrodes 1720, 1730, and 1740 are formed during fabrication of TFLC PIC 1700. Conductive via 1735 may be formed by etching a via through a portion of cladding 1750 covering extension 1730. Thus, extension 1730 is exposed by the via, which is then partially or completely filled with conductive material (e.g., a metal). Channel region 1732 may be formed on cladding 1750 (as shown) or in recesses formed in cladding 1750. Thus, conductive via 1735 and channel region 1732 may be formed during fabrication of TFLC PIC 1700. Conductive vias 1725 and 1745 may be formed by etching through BOX layer 1703 and a portion of cladding 1750 to expose extensions 1720 and 1740, then partially or completely filling the vias. In some embodiments, conductive vias 1725 and 1745 are formed after the substrate (not shown) has been removed and, in some embodiments, BOX layer 1703 has been thinned to the desired thickness. Channel region 1722 may then be formed. Additional dielectric and waveguiding layer 1780 may also be provided on the back side of BOX layer 1703.

Because TFLC waveguides 1710 and 1711 sparsely occupy the footprint of TFLC PIC 1700, formation of conductive vias 1725, 1735, and 1745 may be simplified. In some embodiments, conductive via 1735 and channel region 1732 may be formed after integration of TFLC PIC 1700 with an IC or interposer. In some embodiments, conductive vias 1725 and 1745 and channel region 1722 may be formed after integration of TFLC PIC 1700 with an IC or interposer via flip-chip bonding. Extensions/electrodes 1720, 1730, and 1740, conductive vias 1725, 1735, and 1745, and channel regions/pads 1722 and 1732 may allow for differential driving of both TFLC waveguides 1710. Thus, TFLC PIC 1700 may be driven by lower voltages.

TFLC PIC 1700 may be integrated into a photonics device package in an analogous manner to other TFLC PICs described herein. Thus, the benefits described herein may be achieved. Further, push-pull driving of TFLC waveguides may be accomplished. As a result, a lower voltage may be used to drive modulation of the optical signal transmitted by waveguides 1710.

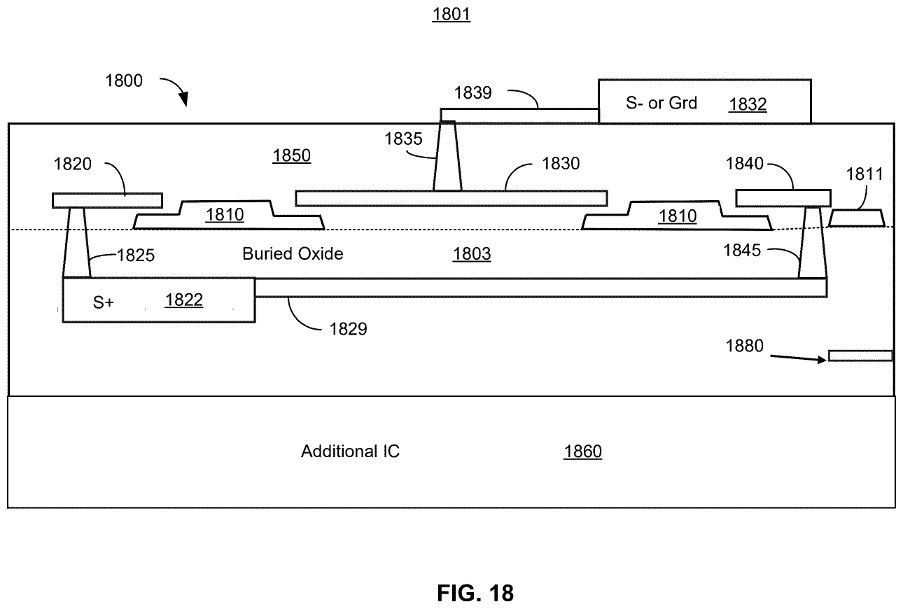

FIG. 18 depicts an embodiment of an integrated photonics package 1801 incorporating an embodiment of TFLC PIC 1800 and IC 1860. Other components are generally present but are not shown for clarity. For example, photonics package 1801 may include electrical input and output (I/O) and/or optical I/O (e.g., a fiber array unit). Although one TFLC PIC 1800 is shown, multiple TFLC PICs and/or multiple additional ICs may be present in particular integrated photonics device packages. Although shown with additional IC 1860, TFLC PIC 1800 may be bonded to a n interposer or other structure. TFLC PIC 1800 is shown right side up, in position for bonding to an underlying interposer or IC.

TFLC PIC 1800 is analogous to TFLC PIC 100. Analogous components are labeled similarly. TFLC PIC 1800 includes TFLC optical component(s) (e.g., TFLC waveguides) 1810, electrodes, and cladding 1850 that may be analogous to TFLC optical component(s) 110/310, electrodes, and cladding 150/350. In the embodiment shown, TFLC waveguides 1810 each includes a slab portion and a rib portion. Other configurations are possible. For example, TFLC PIC 1800 may include waveguides, splitters, bends, mode converters, polarization beam rotators, and/or other optical components used to transmit and/or modify the optical signal carried by TFLC PIC 1800. Electrodes may be used in conjunction with waveguide(s), for example for optical modulation (e.g. via the electro-optic effect). TFLC PIC 1800 also includes additional TFLC waveguide 1811 and additional waveguiding layer 1880 that are analogous to additional waveguide 411 and additional waveguiding layer 580.

TFLC PIC 1800 explicitly includes electrodes 1820, 1830, and 1840. In some embodiments, electrodes 1820, 1830, and 1840 are analogous to extensions 224 and 324. Also shown are channel regions 1822 and 1832 that are analogous to channel regions 222 and 232. Thus, extensions 1820 and 1840 share channel region 1822. Channel regions 1822 and 1832 are coupled to electrodes/extensions 1820, 1830, and 1840 by conductive vias 1825, 1835, and 1845, respectively. Channel regions 1822 and 1832 are also connected with conductive vias 1845 and 1835 via additional extensions 1829 and 1839. Consequently, channel regions 1822 and 1832 may be further from TFLC waveguide 1810. Thus, microwave losses may be mitigated. In other embodiments, structures 1822 and 1832 may be conductive pads, while extensions 1820, 1830, and 1840 may form continuous electrodes.

Extensions/electrodes 1820, 1830, and 1840 are formed during fabrication of TFLC PIC 1800. Conductive via 1835 may be formed by etching a via through a portion of cladding 1850 covering extension 1830. Thus, extension 1830 is exposed by the via, which is then partially or completely filled with conductive material (e.g., a metal). Extension 1839 and channel region 1832 may be formed on cladding 1850 (as shown) or in recesses formed in cladding 1850. Thus, conductive via 1835, extension 1839, and channel region 1832 may be formed during fabrication of TFLC PIC 1800. Conductive vias 1825 and 1845 may be formed by etching through BOX layer 1803 and a portion of cladding 1850 to expose extensions 1820 and 1840, then partially or completely filling the vias. Extension 1829 is also provided to electrically connect conductive via 1845 with channel region 1822. In some embodiments, conductive vias 1825 and 1845 are formed after the substrate (not shown) has been removed and, in some embodiments, BOX layer 1803 has been thinned to the desired thickness. Channel region 1822 and extension 1829 may then be formed. Additional dielectric and waveguiding layer 1880 may also be provided on the back side of BOX layer 1803.

Because TFLC waveguides 1810 and 1811 sparsely occupy the footprint of TFLC PIC 1800, formation of conductive vias 1825, 1835, and 1845 may be simplified. In some embodiments, conductive via 1835 and channel region 1832 may be formed after integration of TFLC PIC 1800 with an IC or interposer. In some embodiments, conductive vias 1825 and 1845 and channel region 1822 may be formed after integration of TFLC PIC 1800 with an IC or interposer via flip-chip bonding. Extensions/electrodes 1820, 1830, and 1840, conductive vias 1825, 1835, and 1845, and channel regions/pads 1822 and 1832 may allow for differential driving of both TFLC waveguides 1810. Thus, TFLC PIC 1800 may be driven by lower voltages.

TFLC PIC 1800 may be integrated into a photonics device package in an analogous manner to other TFLC PICs described herein. Thus, the benefits described herein may be achieved. Further, push-pull driving of TFLC waveguides may be accomplished. As a result, a lower voltage may be used to drive modulation of the optical signal transmitted by waveguides 1810.

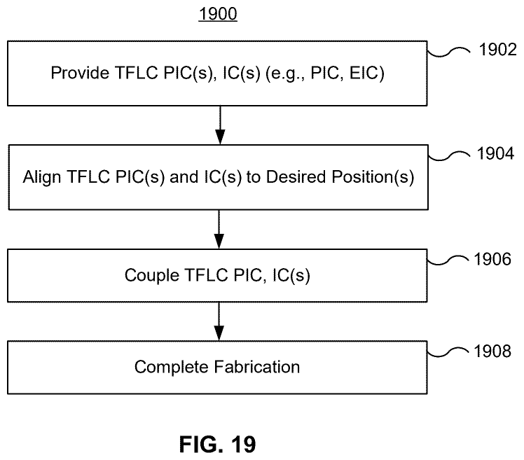

FIG. 19 is a flow-chart depicting an embodiment of method 1900 for providing a photonics package including a TFLC PIC. Method 1900 is described in the context of processes that may have sub-processes. Although described in a particular order, another order not inconsistent with the description herein may be utilized. For example, in some embodiments, portions of processes may be interleaved. Method 1900 is also described in the context of photonics package 100. However, method 1900 may be used with other electro-optic devices including but not limited to photonics packages 101, 101D, 101E, 301, 301D, 301E, 401 501, 601A, 601B, 701, 801, 901, 1001, 1101, 1201, 1301, 1501, and/or 1801 and TFLC PICs 200, 1600, and/or 1700.

The components desired to be integrated are provided, at 1902. Thus, the TFLC PIC(s), IC(s), and interposer(s) to be used are provided. In some embodiments, 1902 includes manufacturing one or more of these components. In some embodiments, the components may be built to specifications or otherwise obtained. For example, 1902 may include fabricating TFLC PIC 100 and obtaining IC 160.

The TFLC PIC(s) and IC(s) are aligned, at 1904. The TFLC PIC(s) and IC(s) are coupled, at 1906. In some embodiments, alignment in 1904 and coupling at 1906 may simply be considered a single step of mechanically coupling the TFLC PIC(s) and the IC(s). In some embodiments, TFLC PIC(s) and/or IC(s) are aligned and mechanically coupled with interposer(s) at 1904 and 1906. As part of 1904 and/04 a906, the TFLC PIC(s) and IC(s) are electrically and optically coupled as appropriate. For example, optical coupling may include aligning waveguides or waveguide(s) and grating(s). Electrically coupling may include aligning conductive vias with pads, performing wire bonding, and/or other analogous tasks. Fabrication is completed, at 1908. Thus, the desired integrated photonic package may be manufactured.

For example, photonics package 100 may be formed using method 1900. IC 160 and TFLC PIC 100 are provided, at 1902. TFLC PIC 100 and IC 160 are aligned and bonded, at 1904 and 1906. In some embodiments, 1904 and/or 1906 may include flipping one of the IC 160 and TFLC PIC 100 for flip-chip bonding. 1904 and 1906 may be considered a single step of mechanically coupling TFLC PIC 100 and IC 160 in the appropriate orientation and alignment. Thus, TFLC photonics package 101 may be provided and the attendant benefits realized.

Although the foregoing embodiments have been described in some detail for purposes of clarity of understanding, the invention is not limited to the details provided. There are many alternative ways of implementing the invention. The disclosed embodiments are illustrative and not restrictive.

What is claimed is:

1. A photonics device package, comprising:
a thin film lithium-containing (TFLC) photonics integrated circuit (PIC), the TFLC PIC including a plurality of TFLC optical structures and a plurality of electrodes, the plurality of TFLC structures including at least one TFLC electro-optic material, at least one TFLC structure of the plurality of TFLC structures including a ridge and a slab and having a width not exceeding one micrometer, the TFLC PIC having a footprint, the plurality of TFLC structures occupying not more than fifty percent of the footprint, the plurality of TFLC structures being encapsulated in the TFLC PIC;
an additional integrated circuit (IC) mechanically coupled with the TFLC PIC after formation of the plurality of TFLC structures.

2. The photonics device package of claim 1, wherein the plurality of TFLC structures occupies not more than ten percent of the footprint and at least one percent of the footprint.

3. The photonics device package of claim 1, wherein the additional IC is electrically coupled with the TFLC PIC through at least one via, the at least one via extending through at least a portion of the TFLC PIC and at least a portion of the additional IC in a region of the footprint not occupied by the plurality of TFLC structures, the at least one via being at least partially filled by a conductive material.

4. The photonics device package of claim 1, wherein the one of the TFLC PIC and the additional IC is flip-chip mounted on the other of the additional IC and the TFLC PIC.

5. The photonics device package of claim 4, wherein the additional IC is selected from an electronic IC and a photonics IC.

6. The photonics device package of claim 5, wherein the additional IC is the electronic IC electrically coupled with the TFLC PIC, and wherein the photonics device package further includes:
the photonics IC, the photonics IC being optically and mechanically coupled with the TFLC PIC and the electronic IC.

7. The photonics device package of claim 1, wherein the photonics device package has an average microwave dielectric index excluding metal areas for a 100 GHz microwave signal for a region at a distance of not more than twenty micrometers centered at the ridge of the at least one TFLC structure of less than 10.

8. The photonics device package of claim 7, wherein the region includes a portion of the TFLC PIC and a portion of the additional IC.

9. The photonics device package of claim 1, wherein at least a portion of the plurality of electrodes is formed after the TFLC PIC and the additional IC are mechanically coupled.

10. The photonics device package of claim 1, wherein the TFLC PIC further includes:
at least one waveguiding structure optically coupled with the at least one TFLC structure.

11. The photonics device package of claim 10, wherein the at least one waveguiding structure surrounds at least a portion of the at least one TFLC structure; and
wherein the at least one waveguiding structure excludes lithium as-fabricated.

12. The photonics device package of claim 1, wherein the at least one TFLC structure includes an intermediate portion between the ridge and the slab, the ridge having a first height, the intermediate portion having a second height less than the first height, the slab having a third height less than the second height.

13. The photonics device package of claim 1, wherein the additional IC is a photonics IC having a waveguide optically coupled with the at least one TFLC structure; and
wherein a portion of the waveguide is adjacent to at least a portion of the slab of the at least one TFLC structure.

14. The photonics device package of claim 13, wherein the photonics IC has a cavity therein, at least a portion of the TFLC PIC being in the cavity.

15. The photonics device package of claim 1, wherein a portion of the at least one TFLC structure is between a first electrode and a second electrode of the plurality of electrodes, the first electrode being closer to the additional IC than the portion of the at least one TFLC structure is, the second electrode being further from the additional IC than the portion of the at least one TFLC structure is.

16. The photonics device package of claim 1, wherein the at least one TFLC structure is between a first electrode and a second electrode, the first electrode and the second electrode forming a differential electrode pair.

17. A photonics device package, comprising:
a thin film lithium-containing (TFLC) photonics integrated circuit (PIC), the TFLC PIC including a plurality of TFLC optical structures, a plurality of electrodes, and an additional waveguiding structure, the plurality of TFLC structures including at least one TFLC electro-optic material, at least one TFLC structure of the plurality of TFLC structures including a ridge and a slab and having a width not exceeding one micrometer, the TFLC PIC having a footprint, the plurality of TFLC structures occupying not more than fifty percent of the footprint, the additional waveguiding structure consisting of an material selected from at least one optical material excluding lithium, the plurality of TFLC structures being encapsulated in the TFLC PIC;
an additional PIC optically and mechanically coupled with the TFLC PIC after formation of the plurality of TFLC structures, the additional PIC including a waveguide, the additional waveguiding structure being configured to optically couple the at least one TFLC structure with the waveguide.

18. A method for forming a photonics device package, comprising:
providing a thin film lithium-containing (TFLC) photonics integrated circuit (PIC), the TFLC PIC including a plurality of TFLC optical structures and a plurality of electrodes, the plurality of TFLC structures including at least one TFLC electro-optic material, at least one TFLC structure of the plurality of TFLC structures including a ridge and a slab and having a width not exceeding one micrometer, the TFLC PIC having a footprint, the plurality of TFLC structures occupying not more than fifty percent of the footprint, the plurality of TFLC structures being encapsulated in the TFLC PIC;
mechanically coupling an additional integrated circuit (IC) with the TFLC PIC after formation of the plurality of TFLC structures.

19. The method of claim 18, further comprising:
forming, after the mechanically coupling, at least one via extending through at least a portion of the TFLC PIC and at least a portion of the additional IC in a region of the footprint not occupied by the plurality of TFLC structures; and
at least partially filling the at least one via with a conductive material such that the additional IC is electrically coupled with the TFLC PIC through at least one via.

20. The method of claim 18, wherein the additional IC is an electronic IC, the method further comprising:
optically and mechanically coupling a photonics IC with the TFLC PIC and the electronic IC.

21. The method of claim 18, wherein the photonics device package has an average microwave dielectric index excluding metal areas for a 100 GHz microwave signal at a distance of not more than twenty micrometers centered at the ridge of the at least one TFLC structure of less than 10.
